(19) United States
(12) Patent Application Publication
(10) Pub. No.: US 2026/0033376 A1
(43) Pub. Date: Jan. 29, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Kyohei Ichiishi, Yokohama-shi (JP); Miki Takahashi, Yokohama-shi (JP); Naoya Suzuki, Yokohama-shi (JP); Toshiki Furutani, Yokohama-shi (JP); Tsutomu Kono, Yokohama-shi (JP)

(21) Appl. No.: 19/273,886

(22) Filed: Jul. 18, 2025

(30) Foreign Application Priority Data
Jul. 24, 2024 (JP) 2024-118403
Dec. 5, 2024 (KR) 10-2024-0179404

(51) Int. Cl. H01L 21/56

(52) U.S. Cl. CPC H01L 21/565; H01L 21/568

(57) ABSTRACT

The adhesive strength and ease of mounting between a circuit board and an encapsulating resin layer are improved and the occurrence of voids is suppressed. A semiconductor device includes a semiconductor chip, a circuit board, and an encapsulating resin layer. The encapsulating resin layer is formed in an encapsulating space including a first encapsulating space formed between the circuit board and the semiconductor chip and a second encapsulating space covering the semiconductor chip. The circuit board has one or more through-holes penetrating from a first surface facing the semiconductor chip toward a second surface, opposite to the first surface, so that the first encapsulating space communicates with the outside of the circuit board. A resin-filled portion formed of the encapsulating resin is formed inside a through-hole, and the circuit board does not have encapsulating resin on the second surface.

### CROSS-REFERENCE TO RELATED APPLICATION(S)

This application claims benefit of priority to Japanese Patent Application No. 2024-118403 filed on Jul. 24, 2024 in the Japan Patent Office and Korean Patent Application No. 10-2024-0179404 filed on Dec. 5, 2024, in the Korean Intellectual Property Office, the disclosures of which are incorporated herein by reference in their entirety.

### BACKGROUND

Manufacturers of conventional semiconductor devices are attempting to improve reliability or secure strength through mold encapsulation using an encapsulating resin. In semiconductor devices, an encapsulating resin layer is formed by filling an encapsulating space including a first encapsulating space, which is a gap between a semiconductor chip and a circuit board, and a second encapsulating space formed by covering an external surface of the semiconductor chip.

However, due to the nature of the fluid, the encapsulating resin first flows in a relatively wide flow range region other than the first encapsulating space, and then flows from four directions of a side surface of the semiconductor chip toward a center of the first encapsulating space. Accordingly, in the semiconductor device, air remaining between the semiconductor chip and the circuit board may not discharged, and voids may be formed. Voids may cause a decrease in the reliability of the semiconductor device, such as a short circuit, in a connection terminal between the semiconductor chip and the circuit board.

### SUMMARY

In related art, the formation of voids may be suppressed by discharging residual air between the semiconductor chip and the circuit board externally through a through-hole penetrating through the circuit board. For example, A device of related art may form and adhere a resin passing through a through-hole formed in a circuit board to a lower surface of the circuit board, so that residual air between a semiconductor chip and the circuit board may be discharged externally through the through-hole by the flow of a resin. Accordingly, the device may suppress occurrence of voids.

In the related art, however, the resin may flow back to the lower surface of the circuit board, thus forming an overflow bead (resin solid). Since the resin solid is difficult to peel off, the device may only be shipped in a state in which the resin solid is attached to the lower surface in a convex shape. Accordingly, when the semiconductor device is mounted on a micro-shaped electronic device product, the remaining solid resin portion becomes an obstacle, making it difficult to make a product smaller and lighter, and there is a problem with ease of mounting.

The present disclosure has been made in consideration of, for example, the above-described problems, and specifically provides a semiconductor device and a method for manufacturing the semiconductor device capable of improving adhesive strength between a circuit board and an encapsulating resin layer and ease of mounting thereof while suppressing the occurrence of voids remaining in a gap between a semiconductor chip and a circuit board.

The above-described aspects are achieved by any one of the following means (1) to (22).
(1) A semiconductor device comprising a circuit board, a semiconductor chip mounted on the circuit board, and an encapsulating resin layer encapsulating the semiconductor chip with an encapsulating resin, wherein the encapsulating resin layer is formed in an encapsulating space including a first encapsulating space formed between the circuit board and the semiconductor chip and a second encapsulating space formed to cover the semiconductor chip, the circuit board has a discharge portion discharging residual air in the first encapsulating space externally, in a position overlapping a projection surface in a thickness direction of the semiconductor chip, a resin-filled portion formed of the encapsulating resin and connected to the encapsulating resin layer formed in the first encapsulating space is formed inside the discharge portion, and the circuit board does not have a solid resin portion formed of the encapsulating resin on a second surface of the circuit board.
(2) The semiconductor device described in item (1) above, wherein the discharge portion is one or more through-holes penetrating from a first surface facing the semiconductor chip to a second surface, opposite to the first surface, so that the first encapsulating space communicates with an outside of the circuit board, in the position overlapping the projection surface in the thickness direction of the semiconductor chip.
(3) The semiconductor device described in item (2) above, wherein the resin-filled portion has a sheared portion in a first end facing the semiconductor chip and a second end, opposite to the first end.
(4) The semiconductor device described in item (3) above, wherein a length from the second end of the resin-filled portion to the second surface of the circuit board is 1/10 or less of a length of the circuit board in a thickness direction.
(5) The semiconductor device described in one of items (2) to (4) above, wherein the circuit board has a cavity portion between a second end, opposite to a first end of the resin-filled portion facing the semiconductor chip, and the second surface.
(6) The semiconductor device described in item (1) above, wherein the discharge portion is one or more through-holes penetrating from the first surface facing the semiconductor chip toward the second surface, opposite to the first surface, so that the first encapsulating space communicates with the outside of the circuit board, in the position overlapping the projection surface in the thickness direction of the semiconductor chip,
the through-hole includes a first hole portion communicating with the first encapsulating space and a second hole portion by which the first hole communicates with the outside of the circuit board, and the second hole portion has a smaller diameter than the first hole portion.
(7) The semiconductor device described in item (6) above, wherein the resin-filled portion has a sheared portion in a second end, opposite to a first end facing the semiconductor chip.
(8) The semiconductor device described in item (6) and (7) above, wherein a length from the second end of the resin-filled portion to the second surface of the circuit board is 1/10 or less of a length of the circuit board in a thickness direction.
(9) The semiconductor device described in one of items (6) to (8) above, wherein the resin-filled portion formed of the encapsulating resin is formed in the first hole portion, and the second hole portion has a cavity formed by the residual air in the first encapsulating space.
(10) The semiconductor device described in one of items (1) to (9) above, wherein the through-hole is formed near a center of the position overlapping the projection surface in the thickness direction of the semiconductor chip
(11) A method for manufacturing a semiconductor device, comprising: forming an encapsulating resin layer encapsulating a semiconductor chip using a mold device, on a module component having a circuit board and the semiconductor chip mounted on the circuit board, wherein the encapsulating resin layer is formed in an encapsulating space including a first encapsulating space formed between the circuit board and the semiconductor chip and a second encapsulating space formed to cover the semiconductor chip, and one or more through-holes are formed in the circuit board, the one or more through-holes penetrating from a first surface facing the semiconductor chip to a second surface, opposite to the first surface, so that the first encapsulating space communicates with an outside of the circuit board, in a position overlapping a projection surface in a thickness direction of the semiconductor chip, and wherein the method for manufacturing a semiconductor device comprises: a disposition process of disposing a carrier substrate on the second surface of the circuit board of the module component; an encapsulating process of injecting an encapsulating resin into a cavity to encapsulate the encapsulating space, in a state in which the module component is disposed in the cavity formed in a mold portion of the mold device; a filling process of filling a portion of the encapsulating resin introduced into the first encapsulating space in the through-hole; a releasing process of releasing the semiconductor device formed of the module component encapsulated with the encapsulating resin from the mold portion, and a peeling process of peeling the carrier substrate from the released semiconductor device.
(12) The method for manufacturing a semiconductor device described in item (11) above, wherein the mold device has an exhaust space formed in the mold portion to communicate with the through-hole, and the method for manufacturing a semiconductor device further includes an air discharge and resin injection process of injecting the encapsulating resin while discharging residual air in the first encapsulating space through the through-hole into the exhaust space, wherein in the peeling process, when peeling the carrier substrate from the semiconductor device, a solid resin portion formed by the encapsulating resin injected into the exhaust space is removed.
(13) A method for manufacturing a semiconductor device, comprising: forming an encapsulating resin layer encapsulating a semiconductor chip using a mold device, in the semiconductor device including a circuit board and the semiconductor chip mounted on the circuit board, wherein the encapsulating resin layer is formed in an encapsulating space including a first encapsulating space formed between the circuit board and the semiconductor chip and a second encapsulating space formed to cover the semiconductor chip, and in the circuit board, one or more through-holes are formed in a position overlapping a projection surface in a thickness direction of the semiconductor chip, the at least one through-hole penetrating from a first surface facing the semiconductor chip to a second surface, opposite to the first surface, so that the first encapsulating space communicates with an outside of the circuit board, wherein the method for manufacturing a semiconductor device comprises: an encapsulating process of forming the encapsulating resin layer by filling a cavity with an encapsulating resin, in a state in which the semiconductor device is disposed in the cavity formed in a mold portion of the mold device; and a filling process of filling the through-hole with the encapsulating resin introduced into the first encapsulating space.
(14) The method for manufacturing a semiconductor device described in item (13) above, wherein the mold device has an exhaust path formed to penetrate from the cavity to an outside of the mold device so as to communicate with the through-hole, and the method for manufacturing a semiconductor device further includes an exhaust process of exhausting residual air in the first encapsulating space from the exhaust path through the through-hole.
(15) The method for manufacturing a semiconductor device described in item (14) above,
wherein the exhaust path is formed by electrical discharge machining and is formed near a center of the position overlapping the projection surface in the thickness direction of the semiconductor chip.
(16) The method for manufacturing a semiconductor device described in item (14) above, wherein the mold portion has a fitting groove formed in a region including a formation position of the exhaust path and a fitting member fitted into the fitting groove, and the exhaust path is a gap formed when the fitting member is fitted into the fitting groove and is formed near a center of the position overlapping the projection surface in the thickness direction of the semiconductor chip.
(17) The method for manufacturing a semiconductor device described in one of items (11) to (16) above, further comprising: a through-hole forming process of forming the one or more through-holes penetrating through the circuit board and communicating with the first encapsulating space in the position overlapping the projection surface in the thickness direction of the semiconductor chip.
(18) The method for manufacturing a semiconductor device described in one of items (11) to (17) above, wherein the through-hole is formed near a center of the position overlapping the projection surface in the thickness direction of the semiconductor chip.
(19) The method for manufacturing a semiconductor device described in one of items (11) to (17) above, wherein the through-hole is formed near a center of the position overlapping the projection surface in the thickness direction of the semiconductor chip by drilling processing from a side of a second surface of the circuit board.
(20) The method for manufacturing a semiconductor device described in one of items (11) to (18) above, wherein the encapsulating resin is a thermosetting resin having a viscosity of more than 0.01 Pa·s in an uncured state.
(21) A semiconductor device manufactured by the method described in one of items (11) to (20) above, wherein a resin-filled portion formed of the encapsulating resin forming the encapsulating resin layer is formed inside the through-hole, the resin-filled portion has a sheared portion formed in a second end, opposite to a first end facing the semiconductor chip, and the circuit board does not have a solid resin portion formed of the encapsulating resin on the second surface.
(22) The semiconductor device manufactured by the method described in one of items (11) to (20) above, wherein a resin-filled portion formed of the encapsulating resin forming the encapsulating resin layer is formed inside the through-hole, and the circuit board has a cavity formed between a second end, opposite to a first end of the resin-filled portion facing the semiconductor chip, and the second surface, and does not have a solid resin portion formed of the encapsulating resin on the second surface.

According to the present disclosure, adhesive strength between a circuit board and an encapsulating resin layer and ease of mounting thereof may be improved while suppressing the occurrence of voids remaining in a gap between a semiconductor chip and a circuit board.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view of a semiconductor device according to some implementations of the present disclosure;

FIG. 1B is a partially enlarged cross-sectional view illustrating the vicinity of a through-hole of a semiconductor device according to some implementations;

FIG. 1C is a partially enlarged view of the vicinity of the through-hole of the semiconductor device according to some implementations;

FIG. 2 is a cross-sectional view illustrating a modified example of a semiconductor device according to some implementations;

FIG. 3A is a cross-sectional view of a semiconductor device according to some implementations of the present disclosure;

FIG. 3B is a partially enlarged cross-sectional view illustrating the vicinity of the through-hole of the semiconductor device according to some implementations;

FIG. 3C is a partially enlarged view of the vicinity of the through-hole of the semiconductor device according to some implementations;

FIG. 4 is a cross-sectional view illustrating a modified example of a semiconductor device according to some implementations;

FIG. 5 is a cross-sectional view of a semiconductor device according to some implementations of the present disclosure;

FIG. 6 is a flowchart of a manufacturing method A which is a manufacturing method for a semiconductor device according to the present disclosure;

FIG. 7A is a view illustrating the manufacturing method A in order of process;

FIG. 7B is a view illustrating the manufacturing method A in order of process;

FIG. 7C is a view illustrating the manufacturing method A in order of process;

FIG. 7D is a view illustrating the manufacturing method A in order of process;

FIG. 7E is a view illustrating the manufacturing method A in order of process;

FIG. 7F is a view illustrating the manufacturing method A in order of process;

FIG. 8 is a flowchart of a manufacturing method B which is a manufacturing method for a semiconductor device according to the present disclosure;

FIG. 9A is a view illustrating the manufacturing method B in order of process;

FIG. 9B is a view illustrating the manufacturing method B in order of process;

FIG. 9C is a view illustrating the manufacturing method B in order of process;

FIG. 9D is a view illustrating the manufacturing method B in order of process;

FIG. 9E is a view illustrating the manufacturing method B in order of process;

FIG. 9F is a view illustrating the manufacturing method B in order of process;

FIG. 9G is a view illustrating the manufacturing method B in order of process;

FIG. 10 is a flowchart of a manufacturing method C which is a manufacturing method for a semiconductor device according to the present disclosure;

FIG. 11A is a view illustrating the manufacturing method C in order of process;

FIG. 11B is a view illustrating the manufacturing method C in order of process;

FIG. 11C is a view illustrating the manufacturing method C in order of process;

FIG. 11D is a view illustrating the manufacturing method C in order of process;

FIG. 12 is a flowchart of a manufacturing method D which is a method for manufacturing a semiconductor device according to the present disclosure;

FIG. 13A is a view illustrating the manufacturing method D in order of process;

FIG. 13B is a view illustrating the manufacturing method D in order of process;

FIG. 13C is a view illustrating the manufacturing method D in order of process;

FIG. 13D is a view illustrating the manufacturing method D in order of process;

FIG. 13E is a view illustrating the manufacturing method D in order of process;

FIG. 14 is a view illustrating another form of an exhaust path;

FIG. 15 is a flowchart of a manufacturing method E which is a manufacturing method for a semiconductor device according to the present disclosure;

FIG. 16A is a view illustrating the manufacturing method E in order of process;

FIG. 16B is a view illustrating the manufacturing method E in order of process;

FIG. 16C is a view illustrating the manufacturing method E in order of process;

FIG. 16D is a view illustrating the manufacturing method E in order of process;

FIG. 17 is a flowchart of a manufacturing method F which is a manufacturing method for a semiconductor device according to the present disclosure;

FIG. 18A is a view illustrating the manufacturing method F in order of process;

FIG. 18B is a view illustrating the manufacturing method F in order of process;

FIG. 18C is a view illustrating the manufacturing method F in order of process;

FIG. 18D is a view illustrating the manufacturing method F in order of process;

FIG. 18E is a view illustrating the manufacturing method F in order of process;

FIG. 19 is a flowchart of a manufacturing method G which is a manufacturing method for a semiconductor device according to the present disclosure;

FIG. 20A is a view illustrating the manufacturing method G in order of process;

FIG. 20B is a view illustrating the manufacturing method G in order of process;

FIG. 20C is a view illustrating the manufacturing method G in order of process;

FIG. 20D is a view illustrating the manufacturing method G in order of process; and

FIG. 20E is a view illustrating the manufacturing method G in order of process.

### DETAILED DESCRIPTION

Hereinafter, example implementations of the present disclosure will be described with reference to the accompanying drawings. In the drawings below, the same reference numerals refer to the same components, and the size of each component in the drawings may be exaggerated for clarity and convenience of explanation. In addition, the example implementations described below are merely exemplary, and various modifications are possible from such example implementations.

Hereinafter, when a constituent element is disposed “above” or “on” to another constituent element, the constituent element may be only directly on the other constituent element or above the other constituent elements in a non-contact manner. Likewise, a constituent element is disposed “below” or “under” to another constituent element, the constituent element may be only directly under the other constituent element or below the other constituent elements in a non-contact manner.

The singular expression includes the plural expression unless the context clearly indicates otherwise. Additionally, when a portion is considered to “comprise,” “include,” or “have” a component, it does not exclude other components, unless otherwise specifically stated, and may additionally include other components.

For the operations performed for the method, if the order is explicitly stated, or if there is no contrary statement, the operations are performed in an appropriate order, and the order in which the operations are described is not necessarily limited. Any use of examples or exemplary terms is merely for the purpose of illustrating the technical concept, and the scope is not limited by the examples or exemplary terms, unless otherwise specified by the scope of the claims.

Meanwhile, in the explanation below, cases in which ordinal numbers such as “first” and “second” are used for explanation are for convenience only and do not specify any order unless specifically stated otherwise.

A configuration of a semiconductor device 1 according to some implementations of the present disclosure will be described.

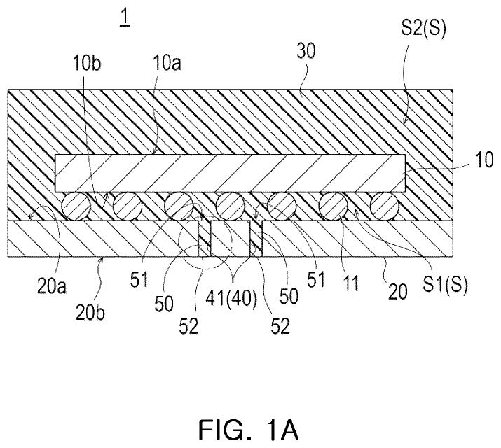

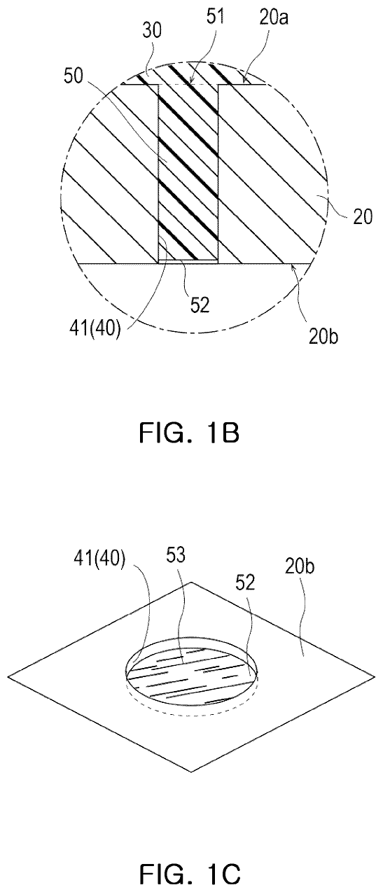

The semiconductor device 1 is configured to include a semiconductor chip 10, a circuit board 20, and an encapsulating resin layer 30, as illustrated in FIG. 1A.

The semiconductor chip 10 is formed of a semiconductor wafer including a semiconductor element such as silicon or a compound semiconductor such as Silicon Carbide (SiC). The semiconductor chip 10 has a first surface 10a and a second surface 10b opposite to the first surface 10a. An IC circuit pattern or the like is formed on the first surface 10a. A connection terminal 11, such as a solder bump for being electrically connected to the circuit board 20, is formed on the second surface 10b. In FIG. 1A, the first surface 10a is an upper surface of the semiconductor chip 10, and the second surface 10b is a lower surface of the semiconductor chip 10.

The circuit board 20 is disposed on a lower side of the semiconductor chip 10. The circuit board 20 is electrically connected to the semiconductor chip 10 through an interconnection portion formed on the board and the connection terminal 11 of the semiconductor chip 10. The circuit board 20 has a first surface 20a and a second surface 20b opposite to the first surface 20a. In FIG. 1A, the first surface 20a is an upper surface of the circuit board 20, and the second surface 20b is a lower surface of the circuit board 20, and functions as a mounting surface for other components.

In the semiconductor device 1, the encapsulating resin layer 30 is formed by filling an encapsulating resin in an encapsulating space S formed in an encapsulating target region of a module component 60 in which the semiconductor chip 10 is mounted on a circuit board 20.

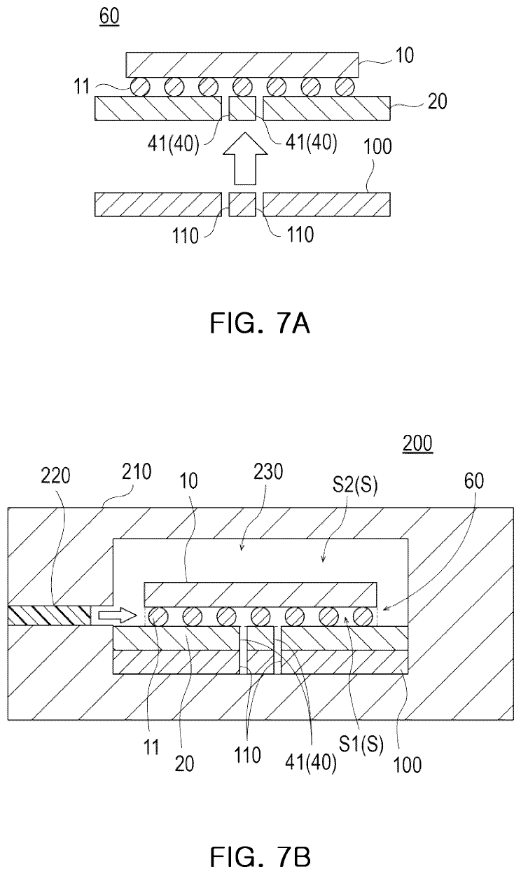

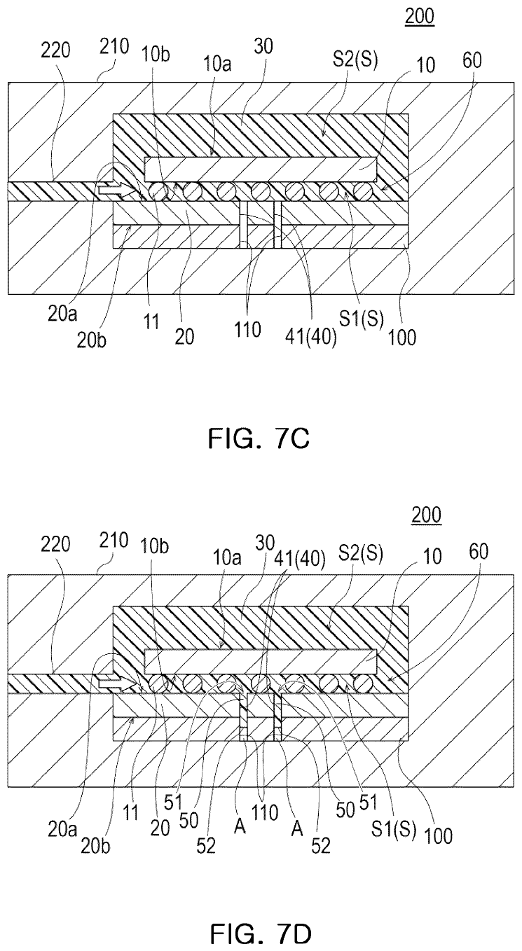

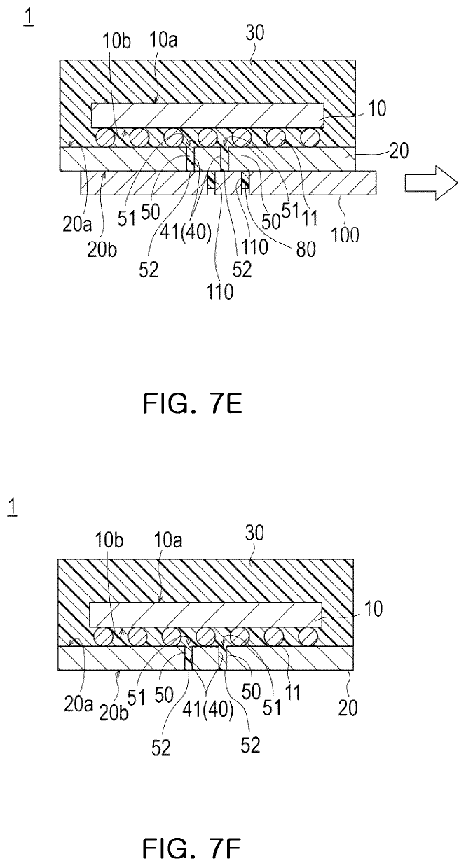

The encapsulating resin layer 30 is formed by an encapsulating resin formed of a thermoplastic resin. The encapsulating resin layer 30 is formed by filling an encapsulating space S with an encapsulating resin. The encapsulating space S may be configured to include, for example, a first encapsulating space S1 formed in a gap between the semiconductor chip 10 and the circuit board 20, as illustrated in FIG. 7B, and a second encapsulating space S2 formed to cover the semiconductor chip 10. In some example implementations, the first encapsulating space S1 is a space surrounded by a dashed line in a manufacturing process drawing such as FIG. 7B, and the second encapsulating space S2 is a space surrounded by a cavity 230 of a mold device 200.

The encapsulating resin is a thermosetting resin having a viscosity at room temperature (e.g., 20° C.) exceeding 0.01 Pa·s in an uncured state. For the encapsulating resin, specifically, epoxy resin, phenol resin, unsaturated polyester resin, or the like, may be suitably used.

At least one discharge portion 40 is formed in the circuit board 20 to discharge residual air A in the first encapsulating space S1 externally. When forming the encapsulating resin layer 30 in the encapsulating space S of the module component 60, the discharge portion 40 discharges residual air A (void) in the first encapsulating space S1 externally. The residual air A in the first encapsulating space S1 is collected near a center of the semiconductor chip 10 by the flow of the encapsulating resin. Accordingly, in consideration of the exhaust efficiency of the residual air A, as illustrated in FIG. 1A, the discharge portion 40 may be preferably formed near a center of a position overlapping a projection surface in a thickness direction of the semiconductor chip 10, the thickness direction being perpendicular to the first surface of the semiconductor chip. For example, the discharge portion 40 may be preferably formed near the center of the semiconductor chip 10 or formed at a position overlapping the center of the semiconductor chip.

The discharge portion 40 may be formed as one or more through-holes 41 penetrating from the first surface 20a to the second surface 20b of the circuit board 20, as illustrated in FIG. 1A. The through-holes 41 communicate with the first encapsulating space S1. Accordingly, the residual air A in the first encapsulating space S1 is discharged from the first encapsulating space S1 externally of the circuit board 20 through the through-holes 41. Additionally, a portion of the encapsulating resin introduced into the first encapsulating space S1 flows in and fills in the through-holes 41.

The number of formed through-holes 41 and a hole diameter thereof may be appropriately set by the viscosity of the encapsulating resin, a length of a gap between the semiconductor chip 10 and the circuit board 20, a thickness of the circuit board 20, a decompression pressure in the mold device 200, an injection pressure of the encapsulating resin, or the like. A hole diameter of the through-hole 41 may be, for example, 0.05 mm or more and 0.1 mm or less.

The through-hole 41 may be formed by drilling processing from a side of the second surface 20b of the circuit board 20. Accordingly, a cut piece when forming the through-hole 41 on the circuit board 20 is suppressed from remaining on the first surface 20a. The through-hole 41 may also be cut together with a carrier substrate 100 disposed on the second surface 20b of the circuit board 20.

When encapsulating the first encapsulating space S1 in the discharge portion 40, if a portion of the encapsulating resin flows in and is filled, a resin-filled portion 50 in which the encapsulating resin is cured is formed inside.

The resin-filled portion 50 is formed by the encapsulating resin filled in the through-hole 41, as illustrated in FIG. 1B. The resin-filled portion 50 has a first end 51 at the semiconductor chip 10 and a second end 52 opposite to the first end 51. A dotted line illustrated in FIG. 1A is a virtual line for indicating the resin-filled portion 50. The resin-filled portion 50 has a sheared portion 53 formed in the second end 52.

As illustrated in FIG. 1C, the sheared portion 53 is formed on an external surface of the second end 52 and is configured to include a concave or convex linear portion or an uneven portion. Accordingly, a cross-section of at least a portion of the second end 52 is a rough surface rather than a smooth surface. Since the sheared portion 53 is formed by shearing a portion of the resin-filled portion 50, the sheared portion 53 may be disposed slightly inside the second surface 20b of the circuit board 20.

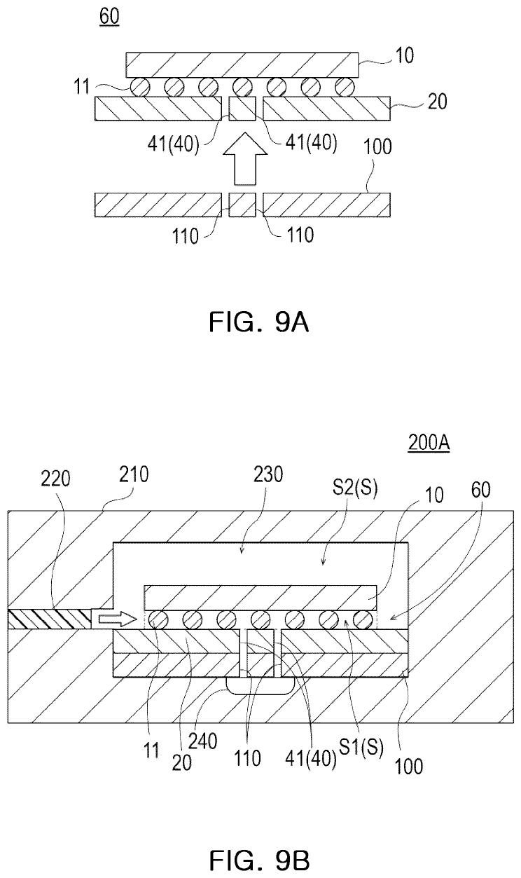

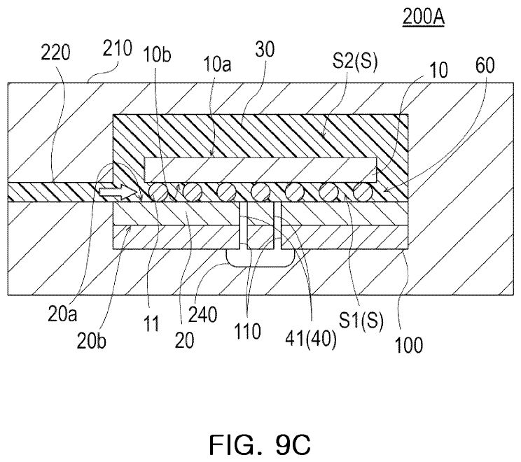

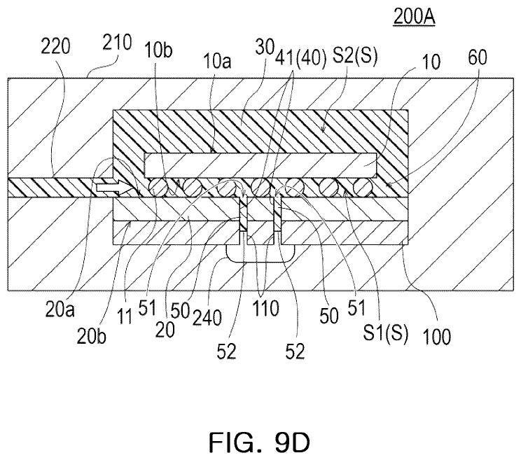

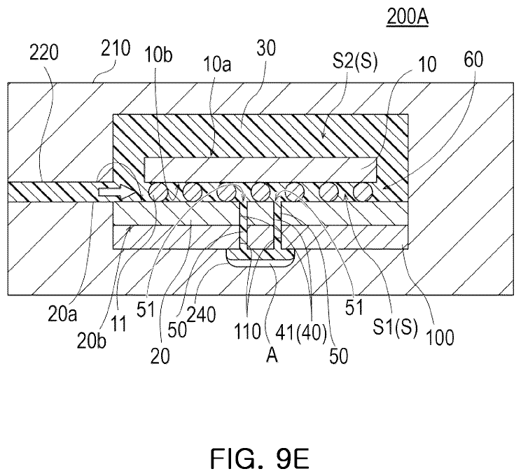

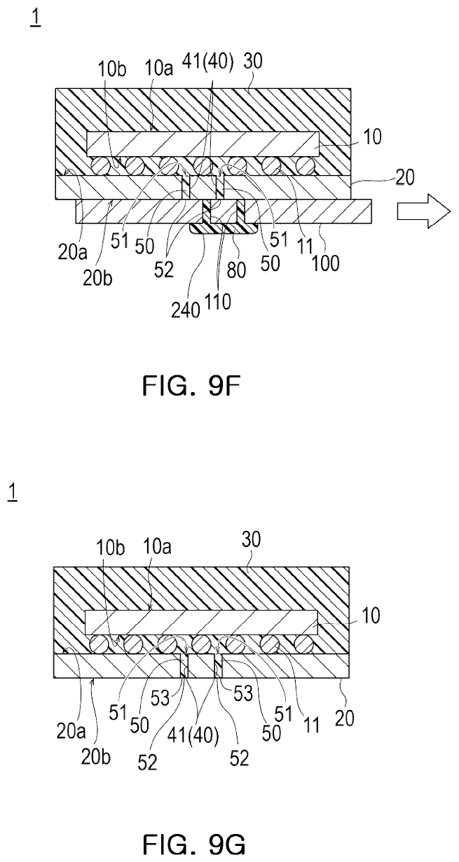

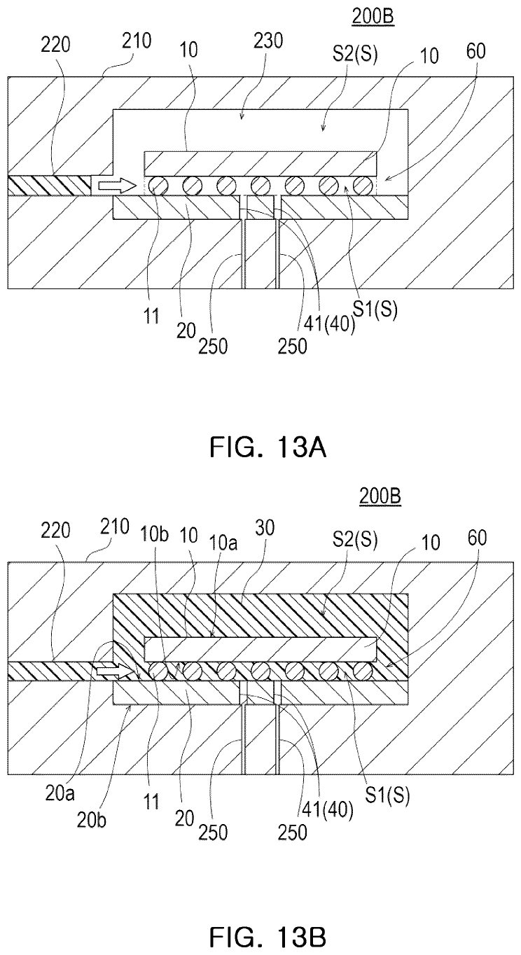

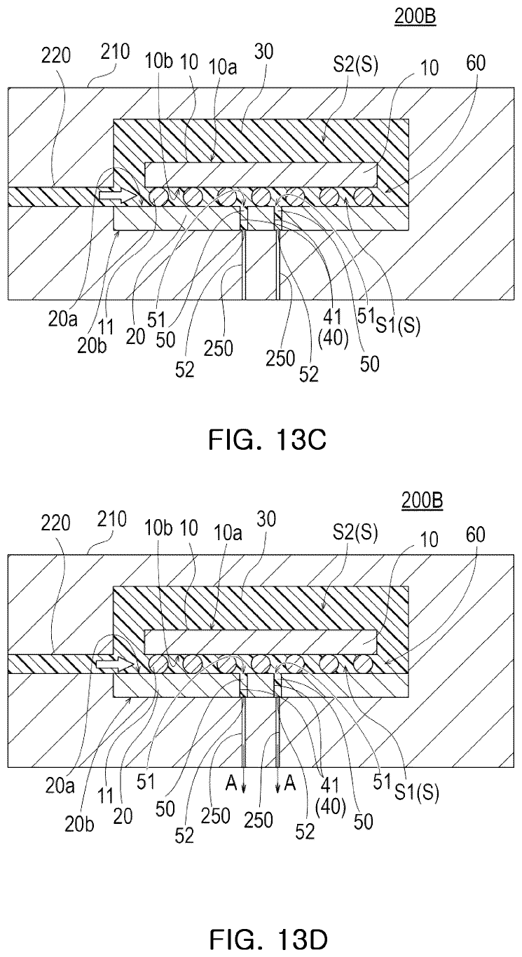

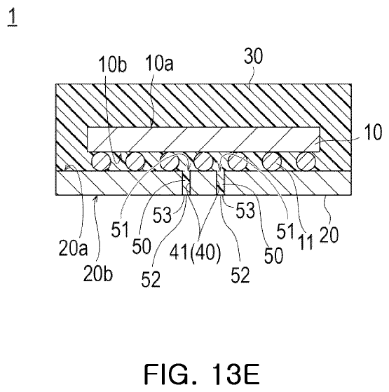

The sheared portion 53 is formed when the carrier substrate 100 disposed on the second surface 20b of the circuit board 20 is peeled off during the manufacturing of the semiconductor device 1. The sheared portion 53 may be formed, for example, when a solid resin portion 80 exposed at the second surface 20b of the circuit board 20 is removed in a peeling process illustrated in FIG. 7E or FIG. 9F. Additionally, the sheared portion 53 may be formed, for example, when the semiconductor device 1 is released from a mold portion 210 after the encapsulating resin layer 30 is formed in a releasing process illustrated in FIG. 13E.

Since the resin-filled portion 50 has a sheared portion 53 in the second end 52, a height of at least a portion of the second end 52 is at least the same height as the second surface 20b of the circuit board 20 or is disposed in the inside of the circuit board 20. Accordingly, in the semiconductor device 1, the solid resin portion 80 exposed to the second surface 20b of the circuit board 20 is not formed, so that the semiconductor device 1 may be mounted without limitation on even a micro-shaped electronic device product.

In the semiconductor device 1, a length from the second end 52 of the resin-filled portion 50 to the second surface 20b of the circuit board 20 may be 1/10 or less of a length of the circuit board 20 in a thickness direction. Accordingly, in the semiconductor device 1, a step portion of the second surface 20b of the circuit board 20 in a position of the through-hole 41 becomes minute. For this reason, the semiconductor device 1 does not require secondary processing such as polishing on the second surface 20b of the circuit board 20 after manufacturing, and may be mounted on micro-shaped devices without limitation.

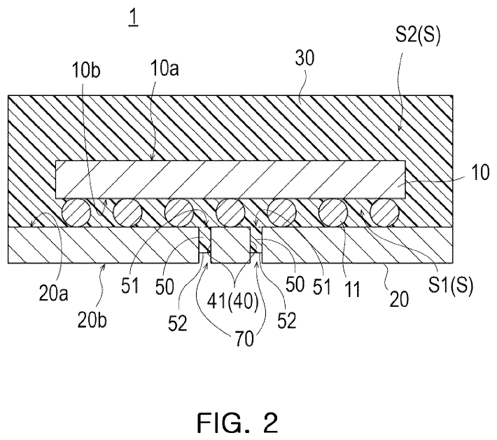

In FIG. 2, a modified example of the semiconductor device 1 of some implementations is illustrated. The semiconductor device 1 may have a cavity portion 70 formed with residual air A between the second end 52 of the resin-filled portion 50 and the second surface 20b of the circuit board 20, as illustrated in FIG. 2. That is, the semiconductor device 1 includes a form in which the entire through-hole 41 is not filled with an encapsulating resin. When the semiconductor device 1 has a cavity portion 70, the second end 52 of the resin-filled portion 50 may be a smooth surface. Since the cavity portion 70 is formed on an opposite side (e.g., a side of a second end 52 of the resin-filled portion 50 in the through-hole 41) from a side facing the encapsulating space S, the problem of short-circuiting of the connection terminal 11 does not occur.

As described above, the semiconductor device 1 of some example implementations includes the circuit board 20, the semiconductor chip 10 mounted on the circuit board 20, and the encapsulating resin layer 30 encapsulating the semiconductor chip 10 with the encapsulating resin. The encapsulating resin layer 30 is formed in the encapsulating space S including a first encapsulating space S1 formed between the circuit board 20 and the semiconductor chip 10 and a second encapsulating space S2 formed to cover the semiconductor chip 10. In the position overlapping the projection surface in the thickness direction of the semiconductor chip 10, the circuit board 20 has one or more through-holes 41 configured to function as a discharge portion 40 penetrating from the first surface 20a toward the second surface 20b so that the first encapsulating space S1 communicates with the outside of the circuit board 20. The resin-filled portion 50 formed of the encapsulating resin is formed inside the through-hole 41, and the circuit board 20 does not have the solid resin portion 80 formed of the encapsulating resin on the second surface 20b.

Since the semiconductor device 1 may discharge the residual air A in the first encapsulating space S1 through the through-hole 41, when forming the encapsulating resin layer 30, the occurrence of voids between the semiconductor chip 10 and the circuit board 20 may be suppressed. Additionally, the resin-filled portion 50 is formed in the discharge portion 40 in the semiconductor device 1, thereby improving adhesive strength between the circuit board 20 and the encapsulating resin layer 30. Furthermore, in the semiconductor device 1, since the solid resin portion 80 by the encapsulating resin is not formed on the second surface 20b of the circuit board 20, the ease of mounting is improved, and thus, the semiconductor device 1 may be mounted on even a micro-shaped electronic device product without limitation.

Next, an example semiconductor device 1A of will be described. The same component for the semiconductor device 1A of some implementations is assigned the same reference numerals as the semiconductor device 1 of the implementations described above, and redundant description thereof will be omitted. Additionally, for points not specifically mentioned, the semiconductor device 1A may be configured similarly to the implementations described above.

The example semiconductor device 1A of differs from the semiconductor device 1 in the shape of the discharge portion 40.

The semiconductor device 1A of some implementations is configured to include a semiconductor chip 10, a circuit board 20, and an encapsulating resin layer 30. In the position overlapping the projection surface in the thickness direction of the semiconductor chip 10, the semiconductor device 1A has one or more through-holes 42 functioning as a discharge portion 40 so that the first encapsulating space S1 communicates with the outside of the circuit board 20.

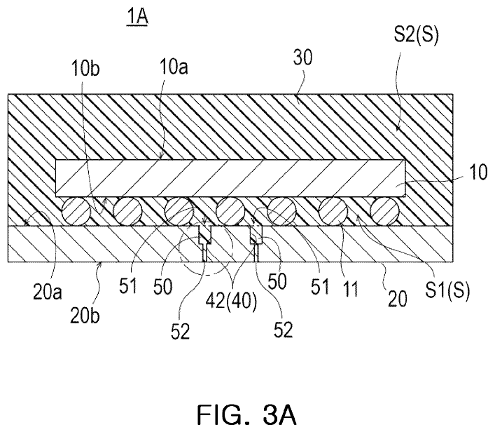

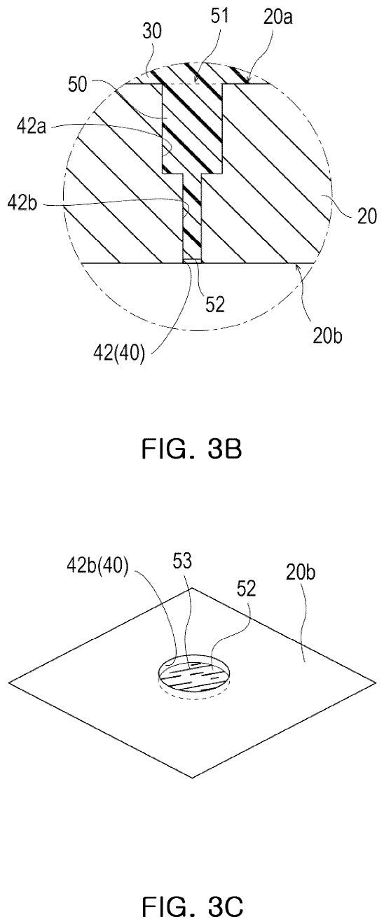

As illustrated in FIG. 3A or FIG. 3B, the through-hole 42 is a multi-stage hole including a first hole portion 42a in a concave shape from the first surface 20a of the circuit board 20 toward the second surface 20b, and a second hole portion 42b penetrating from a bottom of the first hole portion 42a to the second surface 20b so as to communicate with the first hole portion 42a and the outside of the circuit board 20.

As illustrated in FIG. 3B, in the through-hole 42, the first hole portion 42a communicates with the first encapsulating space S1. Accordingly, the residual air A in the first encapsulating space S1 passes through the first hole portion 42a and the second hole portion 42b and is discharged from the first encapsulating space S1 externally of the circuit board 20.

The number of formed first holes 42a and a hole diameter thereof may be appropriately set by the viscosity of the encapsulating resin, a length of a gap between the semiconductor chip 10 and the circuit board 20, a thickness of the circuit board 20, a decompression pressure of the mold device 200, an injection pressure of the encapsulating resin, or the like. A hole diameter of the first hole portion 42a may be set to, for example, 0.05 mm or more and 0.1 mm or less.

A hole diameter of the second hole portion 42b is at least smaller than the hole diameter of the first hole portion 42a. The hole diameter of the second hole portion 42b has a length that allows at least the residual air A and the encapsulating resin in the first encapsulating space S1 to be introduced.

After the residual air A passes through the through-hole 42, some of the encapsulating resin introduced into the first encapsulating space S1 flows in and is filled, and a resin-filled portion 50 is formed.

The resin-filled portion 50 has a first end 51 at the semiconductor chip 10 and a second end 52 opposite to the first end 51. The resin-filled portion 50 has a sheared portion 53 in the second end 52, as illustrated in FIG. 3C. A dotted line illustrated in FIG. 3A is a virtual line for specifying the resin-filled portion 50. The sheared portion 53 is formed by shearing a portion of the resin-filled portion 50, so that at least a portion thereof may be disposed slightly inside the second surface 20b of the circuit board 20. For this reason, the circuit board 20 does not have a solid resin portion 80 formed of an encapsulating resin on the second surface 20b.

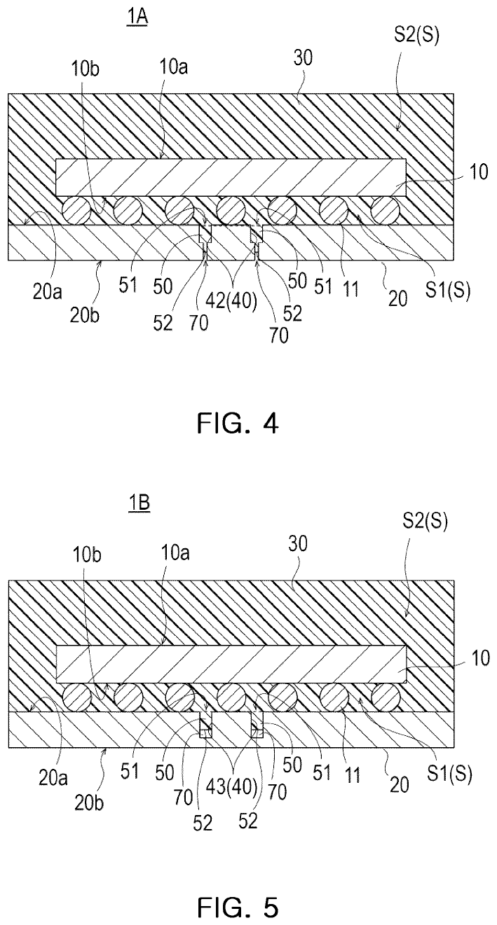

A modified example of the semiconductor device 1A is illustrated in FIG. 4. As illustrated in FIG. 4, the semiconductor device 1A may have a resin-filled portion 50 formed in a portion of the second hole portion 42b, and may have a cavity portion 70 formed of residual air A in the other portion.

The cavity portion 70 may be formed when the amount of encapsulating resin introduced into the second hole portion 42b is small. Additionally, the cavity portion 70 may be formed on the entire inside of the second hole portion 42b when the hole diameter of the second hole portion 42b is a length that allows only the residual air A to be circulated. That is, the semiconductor device 1A may include a form in which the resin-filled portion 50 is formed in at least a portion of the second hole portion 42b or a form in which the resin-filled portion 50 is not formed in the second hole portion 42b. When the semiconductor device 1A has the cavity portion 70, the second end 52 of the resin-filled portion 50 may be a smooth surface.

As described above, since the semiconductor device 1A is able to discharge the residual air A in the first encapsulating space S1 through the through-hole 42, the occurrence of voids between the semiconductor chip 10 and the circuit board 20 may be suppressed when forming the encapsulating resin layer 30. Additionally, since the semiconductor device 1A has a resin-filled portion 50 formed in the through-hole 42, bonding strength between the circuit board 20 and the encapsulating resin layer 30 is improved. Furthermore, in the semiconductor device 1A, since the solid resin portion 80 by the encapsulating resin is not formed on the second surface 20b of the circuit board 20, the ease of mounting is improved, and the semiconductor device 1A may be mounted on even a micro-shaped electronic device product without limitation.

Next, an example semiconductor device 1B of will be described. In the example semiconductor device 1B, the same component as the example semiconductor device 1 of or the example semiconductor device 1A of described above is assigned the same reference numerals, and redundant description thereof will be omitted. Additionally, for points not specifically mentioned, the example semiconductor device 1B may be configured similarly to the implementations described above.

The example semiconductor device 1B of differs from the semiconductor devices 1 and 1A in the shape of the discharge portion 40.

The example semiconductor device 1B of is configured to include a semiconductor chip 10, a circuit board 20, and an encapsulating resin layer 30. The semiconductor device 1B has at least one groove portion 43 functioning as the discharge portion 40 so as to communicate with the first encapsulating space S1 in the position overlapping the projection surface in the thickness direction of the semiconductor chip 10.

The groove portion 43 may be formed in a concave shape from the first surface 20a of the circuit board 20 toward the second surface 20b, as illustrated in FIG. 5. The groove portion 43 communicates with the first encapsulating space S1, and the residual air A in the first encapsulating space S1 is discharged. Additionally, a portion of the encapsulating resin introduced into the first encapsulating space S1 flows and is filled in the groove portion 43. The groove portion 43 should have a depth and an opening diameter that allow the encapsulating resin to be introduced while at least accommodating the residual air A discharged from the first encapsulating space S1.

The groove portion 43 has a resin-filled portion 50 formed inside. The resin-filled portion 50 has a first end 51 at the semiconductor chip 10, and a second end 52 opposite to the first end 51. A dotted line illustrated in FIG. 5 is a virtual line for specifying the resin-filled portion 50. In the semiconductor device 1B, the second end 52 of the resin-filled portion 50 may be a smooth surface. A cavity portion 70 formed of residual air A is formed between the resin-filled portion 50 and the groove portion 43.

As described above, the semiconductor device 1B includes the circuit board 20, the semiconductor chip 10 mounted on the circuit board 20, and the encapsulating resin layer 30 encapsulating the semiconductor chip 10 with the encapsulating resin. The encapsulating resin layer 30 is formed in the encapsulating space S including the first encapsulating space S1 formed between the circuit board 20 and the semiconductor chip 10 and the second encapsulating space S2 formed to cover the semiconductor chip 10. The circuit board 20 has one or more groove portions 43 functioning as a discharge portion 40 formed in a concave shape from the first surface 20a toward the second surface 20b so as to communicate with the first encapsulating space S1, in the position overlapping the projection surface in the thickness direction of the semiconductor chip 10. Inside the groove portions 43, the resin-filled portion 50 formed of the encapsulating resin is formed, and the cavity portion 70 formed of the residual air A is formed between the resin-filled portion 50 and the groove portions 43.

In the semiconductor device 1B, since the residual air A in the first encapsulating space S1 may be discharged to the groove portions 43, when forming the encapsulating resin layer 30, the occurrence of voids between the semiconductor chip 10 and the circuit board 20 may be suppressed. Additionally, in the semiconductor device 1B, since the resin-filled portion 50 is formed in the groove portion 43, the bonding strength between the circuit board 20 and the encapsulating resin layer 30 is improved. Furthermore, in the semiconductor device 1B, since the solid resin portion 80 by the encapsulating resin is not formed on the second surface 20b of the circuit board 20, the case of mounting is improved, and the semiconductor device 1B may be mounted on even a micro-shaped electronic device product without limitation.

Next, a method for manufacturing a semiconductor device will be described.

A method for manufacturing a semiconductor device (manufacturing method A to manufacturing method G) according to some example implementations of the present disclosure is a method for forming an encapsulating resin layer 30 by filling the encapsulating resin in the encapsulating space S of the module component 60 included in the semiconductor devices 1, 1A and 1B. Meanwhile, each of the manufacturing methods illustrated below may appropriately change the implementation order or include other processes without departing from the implementations described in the present disclosure.

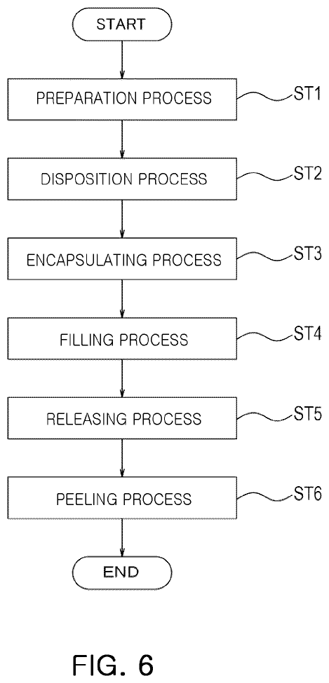

A first example manufacturing method, a semiconductor device manufacturing method (hereinafter referred to as “manufacturing method A”), is now described. FIG. 6 is a flow chart illustrating a series of processes of manufacturing method A. FIGS. 7A to 7F are configuration diagrams illustrating the processes of the manufacturing method A.

The mold device 200 used in the manufacturing method A is configured to include, as illustrated in FIG. 7B and the like, a mold portion 210 forming a cavity 230 in which a module component 60 is disposed, and one or more injection paths 220 injecting an encapsulating resin into the cavity 230. The mold device 200 injects the encapsulating resin while depressurizing the inside of the cavity 230 and applying a uniform pressure. The mold portion 210 is divided into a plurality of portions in order to make the semiconductor device 1 detachable. The mold portion 210 may be moved by a driving mechanism. The injection mold 220 is disposed on a side surface of the mold portion 210. The encapsulating resin is stored in a container and injected into the cavity 230 through the injection mold 220. Meanwhile, the mold device 200 may further include components other than the above-described components.

As illustrated in FIG. 6, the manufacturing method A includes a preparation process ST1, a disposition process ST2, an encapsulating process ST3, a filling process ST4, a releasing process ST5, and a peeling process ST6. Hereinafter, the manufacturing method A is described as a method for manufacturing a semiconductor device 1.

In the preparation process ST1, a module component 60 included in the semiconductor device 1, a carrier substrate 100 disposed on the circuit board 20 of the module component 60, and a mold device 200 used to form the encapsulating resin layer 30 are prepared, respectively.

In the disposition process ST2, as illustrated in FIG. 7A, the carrier substrate 100 is disposed on the second surface 20b of the circuit board 20 of the module component 60. Accordingly, in the module component 60, the carrier substrate 100 is disposed on the circuit board 20.

The carrier substrate 100 has a carrier substrate through-hole 110 communicating with the through-hole 41. The carrier substrate through-hole 110 may be formed in advance to match a formation position of the through-hole 41 formed in the circuit board 20, or may be formed at the same time when the through-hole 41 is formed in the circuit board 20.

In the encapsulating process ST3, as illustrated in FIG. 7B and FIG. 7C, in a state in which the module component 60 is disposed in the cavity 230 formed by the mold portion 210 of the mold device 200, the encapsulating resin is filled in the cavity 230 to form an encapsulating resin layer 30 in the encapsulating space S. The encapsulating resin flows to fill the second encapsulating space S2 having a relatively wide flow range, in the cavity 230, and then flows from four directions of side surfaces of the semiconductor chip 10 toward the center of the first encapsulating space S1. In the module component 60, the encapsulating resin is filled in the encapsulating space S (e.g., the first encapsulating space S1 and the second encapsulating space S2), and thus, an encapsulating resin layer 30 is formed, and a semiconductor device 1 is formed.

In the filling process ST4, as illustrated in FIG. 7D, a portion of the encapsulating resin injected into the cavity 230 in the encapsulating process ST3 is filled into the through-hole 41 and the carrier substrate through-hole 110.

As illustrated in FIGS. 7B and 7C, the encapsulating resin is first introduced into the second encapsulating space S2, and may gradually flow toward the vicinity of a center of the first encapsulating space S1 having a small flow path width by changing a flow direction thereof. For this reason, the residual air A in the first encapsulating space S1 gathers near the center of the first encapsulating space S1 along with the flow of the encapsulating resin. Then, as illustrated in FIG. 7D, the encapsulating resin pushes the residual air A in the first encapsulating space S1 into the through-hole 41 and flows into the through-hole 41 and the carrier substrate through-hole 110 and fills the same. Accordingly, the residual air A passes through the through-hole 41 and moves into the carrier substrate through-hole 110.

In the filling process ST4, the filled encapsulating resin is filled into the through-hole 41 in the process of pushing the residual air A into the through-hole 41, and a portion thereof may flow into the carrier substrate through-hole 110 of the carrier substrate 100. The encapsulating resin filled into the through-hole 41 and the carrier substrate through-hole 110 forms a filled resin portion 50.

In the releasing process ST5, the semiconductor device 1 on which the encapsulating resin layer 30 is formed is released from the mold portion 210.

In the peeling process ST6, as illustrated in FIG. 7E, the carrier substrate 100 is peeled from the semiconductor device 1. In the peeling process ST6, the carrier substrate 100 is moved in parallel with the second surface 20b of the circuit board 20 and then peeled. The second end 52 of the resin-filled portion 50 formed in the through-hole 41 is attached to the vicinity of the opening of the carrier substrate through-hole 110 formed in the carrier substrate 100 before peeling the carrier substrate 100. For this reason, the carrier substrate 100 is peeled in a state in which a portion of the resin-filled portion 50 is attached to the vicinity of the opening of the carrier substrate through-hole 110. Accordingly, as illustrated in FIG. 1B, in the semiconductor device 1, a portion of the resin-filled portion 50 is sheared, and a sheared portion 53 is formed in the second end 52 of the resin-filled portion 50. Then, the semiconductor device 1 is completed through the peeling process ST6 as illustrated in FIG. 7F.

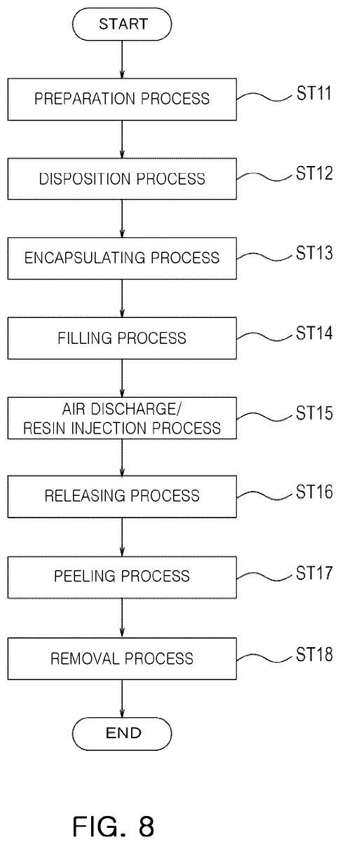

A second example manufacturing method, an example semiconductor device manufacturing method (hereinafter referred to as “manufacturing method B”), will be described. FIG. 8 is a flow chart illustrating a series of processes of the manufacturing method B. FIGS. 9A to 9G are configuration diagrams illustrating the processes of the manufacturing method B.

The manufacturing method B differs from the manufacturing method A in that the residual air A is discharged to an exhaust space 240 formed in the mold portion 210 of the mold device 200.

A mold device 200A used in the manufacturing method B is configured to include a mold portion 210 forming a cavity 230, one or more injection paths 220 for injecting an encapsulating resin into the cavity 230, and an exhaust space 240, as illustrated in FIG. 9B. The mold device 200A has the same configuration and function as the mold device 200 described above, except that the mold device 200A has the exhaust space 240. The exhaust space 240 is formed in the mold portion 210. The exhaust space 240 is partially filled with the residual air A and the encapsulating resin of the first encapsulating space S1 discharged through the through-hole 41 and the carrier substrate through-hole 110. Meanwhile, the mold device 200A may include components other than the components described above.

As illustrated in FIG. 8, the manufacturing method B includes a preparation process ST11, a disposition process ST12, an encapsulating process ST13, a filling process ST14, an air discharge/resin injection process ST15, a releasing process ST16, a peeling process ST17, and a removal process ST18. Hereinafter, the manufacturing method B is described as a method for manufacturing a semiconductor device 1.

In the preparation process ST11, a module component 60 included in a semiconductor device 1, a carrier substrate 100 disposed on a circuit board 20 of the module component 60, and a mold device 200A used to form an encapsulating resin layer 30 are prepared, respectively.

In the disposition process ST12, as illustrated in FIG. 9A, the carrier substrate 100 is disposed on the second surface 20b of the circuit board 20 of the module component 60. Accordingly, in the module component 60, the carrier substrate 100 is disposed on the circuit board 20.

In the encapsulating process ST13, as illustrated in FIGS. 9B and 9C, in a state in which the module component 60 is disposed in the cavity 230 formed by the mold portion 210 of the mold device 200A, the encapsulating resin is filled in the cavity 230 to form an encapsulating resin layer 30 in the encapsulating space S.

As illustrated in FIG. 9D, in the filling process ST14, a portion of the encapsulating resin injected into the cavity 230 in the encapsulating process ST13 is filled into the through-hole 41 and the carrier substrate through-hole 110. The residual air A moves to the carrier substrate through-hole 110 by the inflow of the encapsulating resin into the through-holes 41 and 110. The encapsulating resin filled into the through-hole 41 and the carrier substrate through-hole 110 forms a filled resin portion 50.

As illustrated in FIG. 9E, in the air discharge/resin injection process ST15, while the residual air A passing through the through-hole 41 and the carrier substrate through-hole 110 is discharged into the exhaust space 240, a portion of the encapsulating resin is injected into the exhaust space 240. A movement of residual air A may occur by the inflow of the encapsulating resin into the through-hole 41 and carrier substrate through-hole 110. Accordingly, the exhaust space 240 is partially filled with the residual air A and the encapsulating resin.

In the releasing process ST16, the semiconductor device 1 in which the encapsulating resin layer 30 is formed is released from the mold portion 210.

As illustrated in FIG. 9F, in the peeling process ST17, the carrier substrate 100 is peeled from the semiconductor device 1. In the peeling process ST17, when the carrier substrate 100 disposed on the circuit board 20 is peeled, the solid resin portion 80 formed of the encapsulating resin injected into the inside of the carrier substrate through-hole 110 and the exhaust space 240 is removed. Accordingly, the semiconductor device 1 is in a state in which there is no solid resin portion 80 on the second surface 20b of the circuit board 20. Additionally, a sheared portion 53 is formed on the second end 52 of the filled resin portion 50 by peeling off the carrier substrate 100. Then, the semiconductor device 1 is completed through the peeling process ST17, as illustrated in FIG. 9G.

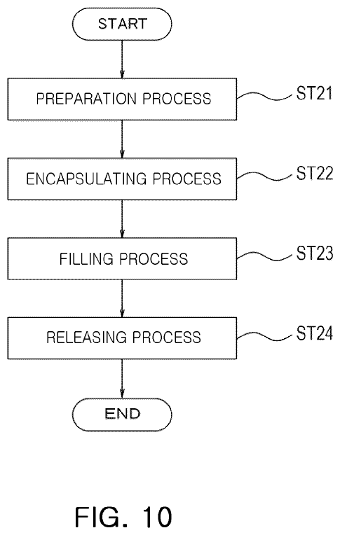

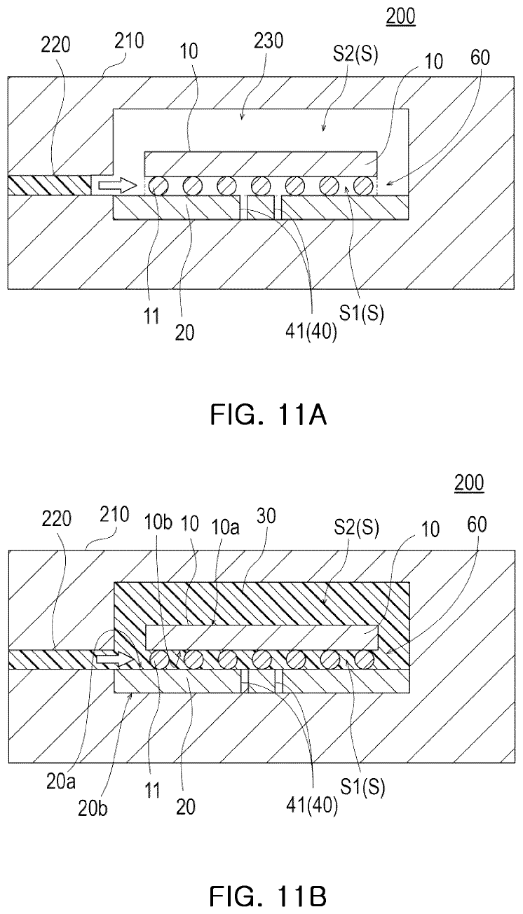

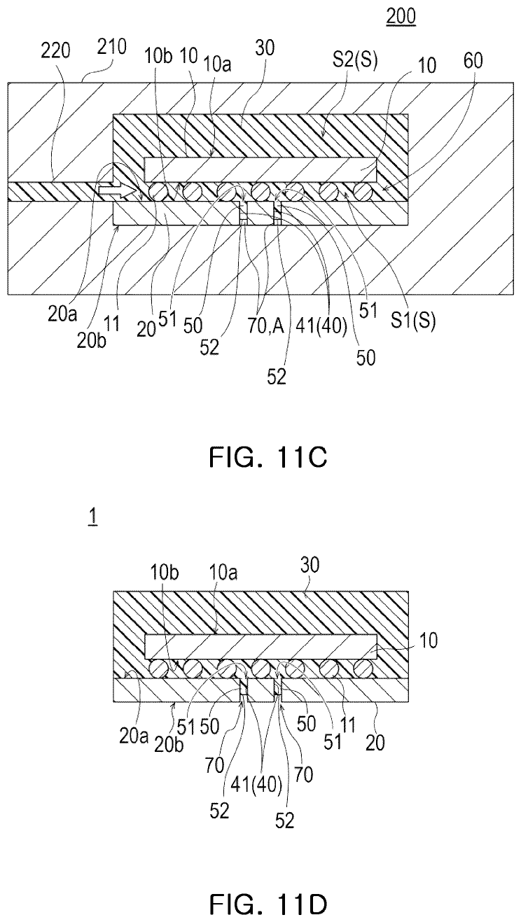

Next, a third example manufacturing method, an example semiconductor device manufacturing method (hereinafter referred to as “manufacturing method C”), will be described. FIG. 10 is a flow chart illustrating a series of processes of the manufacturing method C. FIGS. 11A to 11D are configuration diagrams illustrating the processes of the manufacturing method C.

The manufacturing method C differs from the manufacturing method A in that the carrier substrate 100 is not disposed on the circuit board 20 and the cavity portion 70 is formed by discharging the residual air A into the through-hole 41.

The manufacturing method C includes a preparation process ST21, an encapsulating process ST22, a filling process ST23, and a releasing process ST24, as illustrated in FIG. 10. Hereinafter, the manufacturing method C is described as a method for manufacturing a semiconductor device 1.

In the preparation process ST21, a module component 60 included in the semiconductor device 1 and a mold device 200 used to form an encapsulating resin layer 30 are prepared, respectively.

As illustrated in FIGS. 11A and 11B, in the encapsulating process ST22, in a state in which the module component 60 is disposed in a cavity 230 formed by a mold portion 210 of the mold device 200, an encapsulating resin is filled into the cavity 230 to form an encapsulating resin layer 30 in an encapsulating space S.

As illustrated in FIG. 11C, in the filling process ST23, a portion of the encapsulating resin injected into the cavity 230 in the encapsulating process ST22 is filled into the through-hole 41. The residual air A moves into the through-hole 41. A movement of the residual air A may occur by the inflow of the encapsulating resin into the through-hole 41. The residual air A moved into the through-hole 41 forms a cavity portion 70 at the second end 52 of the resin-filled portion 50 inside the through-hole 41.

In the releasing process ST24, the semiconductor device 1 in which the encapsulating resin layer 30 is formed is released from the mold portion 210. Then, the semiconductor device 1 is completed through the releasing process ST24, as illustrated in FIG. 11D.

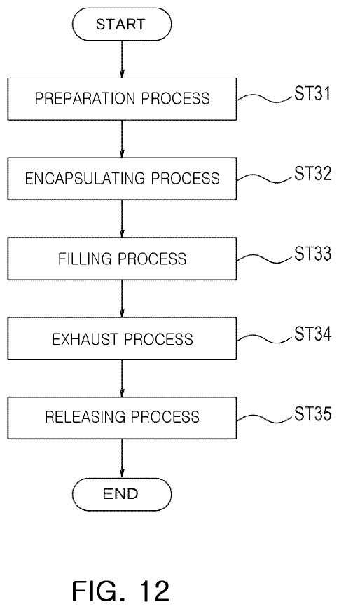

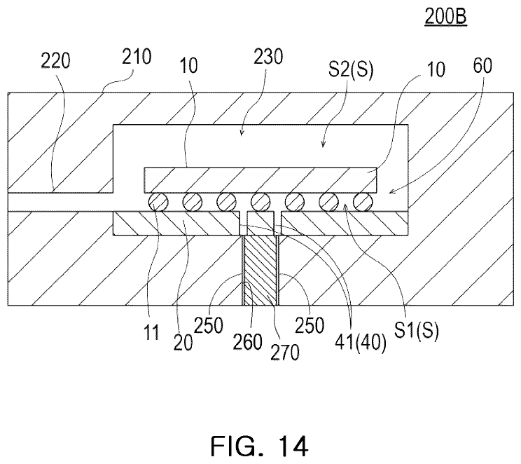

Next, a fourth example manufacturing method, an example semiconductor device manufacturing method (hereinafter referred to as “manufacturing method D”), will be described. FIG. 12 is a flow chart illustrating a series of processes of the manufacturing method D. FIGS. 13A to 13E are configuration diagrams illustrating the processes of the manufacturing method D. FIG. 14 is a view illustrating a modified example of the mold device 200 used in the manufacturing method D.

The manufacturing method D differs from the manufacturing method A in that the carrier substrate 100 is not disposed on the circuit board 20, and the residual air A is discharged through an exhaust path 250 penetrating from the cavity 230 externally of the mold device 200.

As illustrated in FIG. 13B, a mold device 200B used in the manufacturing method D is configured to include a mold portion 210 forming a cavity 230, one or more injection paths 220 for injecting an encapsulating resin into the cavity 230, and an exhaust path 250. The mold device 200B has the same configuration and function as the mold device 200 described above, except that the mold device 200B has the exhaust path 250. The mold device 200B may further include other components than the components described above.

The exhaust path 250 is formed to communicate with the through-hole 41 in the mold portion 210. The exhaust path 250 is formed near a center of the position overlapping the projection surface in the thickness direction of the semiconductor chip 10. The exhaust path 250 has a hole diameter through which only residual air A is able to flow. The exhaust path 250 exhausts residual air A of the first encapsulating space S1 discharged through the through-hole 41 externally of the mold device 200B.

The exhaust path 250 may be formed by performing electrical discharge processing on the mold portion 210. Additionally, the exhaust path 250 is formed to be detachable in a portion of the mold portion 210, as illustrated in FIG. 14, and may be formed in a gap formed when a fitting member 270 is fitted into a fitting groove 260 formed in the mold portion 210. Meanwhile, the exhaust path 250 is formed to have a hole diameter that allows only the residual air A to be discharged externally of the mold portion 210, which is not limited to the above-described forming method.

As illustrated in FIG. 12, the manufacturing method D includes a preparation process ST31, an encapsulating process ST32, a filling process ST33, an exhaust process ST34, and a releasing process ST35. Hereinafter, the manufacturing method D is described as a manufacturing method of a semiconductor device 1.

In the preparation process ST31, the module component 60 included in the semiconductor device 1 and the mold device 200B used to form the encapsulating resin layer 30 are prepared, respectively.

As illustrated in FIGS. 13A and 13B, in the encapsulating process ST32, in a state in which the module component 60 is disposed in the cavity 230 formed by the mold portion 210 of the mold device 200B, the encapsulating resin is filled in the cavity 230 to form the encapsulating resin layer 30 in the encapsulating space S.

As illustrated in FIG. 13C, in the filling process ST33, a portion of the encapsulating resin injected into the cavity 230 in the encapsulating process ST13 is filled in the through-hole 41. The residual air A moves to the through-hole 41. A movement of the residual air A may occur by the inflow of the encapsulating resin into the through-hole 41. The encapsulating resin filled in the through-hole 41 forms a resin-filled portion 50.

As illustrated in FIG. 13D, in the exhaust process ST34, the mold device 200B exhausts the residual air A passing through the through-hole 41 externally through the exhaust path 250. A movement of the residual air A may occur by the inflow of the encapsulating resin into the through-hole 41.

In the releasing process ST35, the semiconductor device 1 in which the encapsulating resin layer 30 is formed is released from the mold portion 210. The second end 52 of the resin-filled portion 50 formed in the through-hole 41 may be attached to a bottom of the mold portion 210 before the releasing process. For this reason, the semiconductor device 1 is released in a state in which a portion of the resin-filled portion 50 is attached to the mold portion 210 near an opening of the through-hole 41. Accordingly, as illustrated in FIG. 1B, in the semiconductor device 1, a portion of the resin-filled portion 50 is sheared, and a sheared portion 53 may be formed in the second end 52 of the resin-filled portion 50. Then, the semiconductor device 1 is completed through the releasing process ST35, as illustrated in FIG. 13E.

On the other hand, in the manufacturing method D, in the filling process ST33, the encapsulating resin is introduced into the through-hole 41 to form the resin-filled portion 50. However, the encapsulating resin may be accumulated inside the through-hole 41 due to the amount of the encapsulating resin introduced into the through-hole 41 and may not be attached to the mold portion 210. In this case, in the through-hole 41, as illustrated in FIG. 2, a cavity portion 70 is formed at the second end 52 of the resin-filled portion 50.

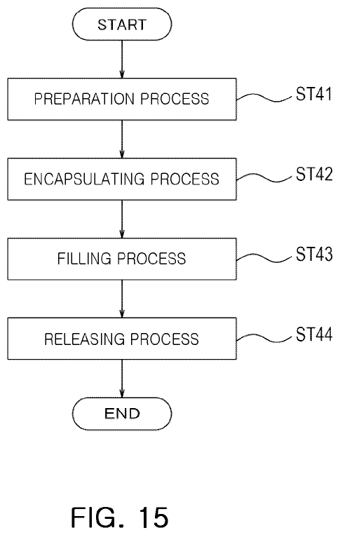

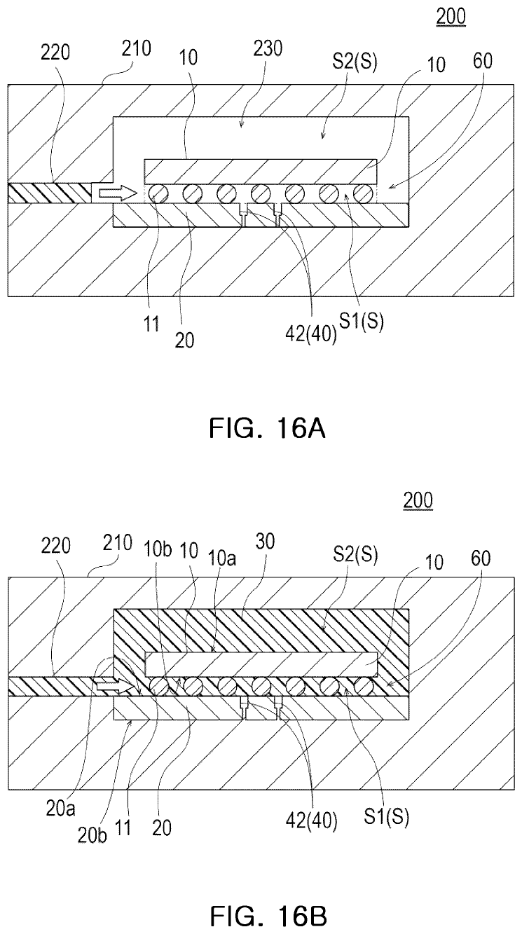

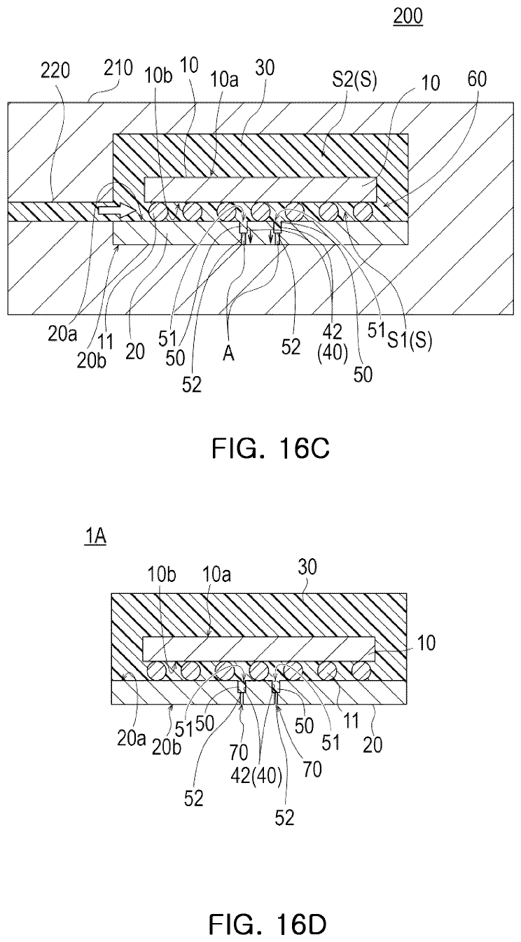

Next, a fifth example manufacturing method, an example semiconductor device manufacturing method (hereinafter referred to as “manufacturing method E”), will be described. FIG. 15 is a flow chart illustrating a series of processes of the manufacturing method E. FIGS. 16A to 16D are configuration diagrams illustrating the processes of the manufacturing method E. The manufacturing method E differs from the manufacturing method A in that the carrier substrate 100 is not disposed on the circuit board 20 and the cavity portion 70 is formed by discharging the residual air A into the second hole portion 42b of the through-hole 42. The manufacturing method E uses a mold device 200 as illustrated in FIG. 16A.

The manufacturing method E includes a preparation process ST41, an encapsulating process ST42, a filling process ST43, and a releasing process ST44, as illustrated in FIG. 15. Hereinafter, the manufacturing method E is described as a manufacturing method of a semiconductor device 1A.

In the preparation process ST41, a module component 60 included in the semiconductor device 1A and a mold device 200 used to form an encapsulating resin layer 30 are prepared, respectively.

In the encapsulating process ST42, as illustrated in FIG. 16A, in a state in which the module component 60 is disposed in the cavity 230 formed by the mold portion 210 of the mold device 200, the encapsulating resin is filled in the cavity 230 to form an encapsulating resin layer 30 in the encapsulating space S.

In the filling process ST43, as illustrated in FIG. 16B and FIG. 16C, a portion of the encapsulating resin injected into the cavity 230 in the encapsulating process ST42 is filled into the through-hole 42. The encapsulating resin is filled at least in the first hole portion 42a of the through-hole 42, and may also be partially introduced into the second hole portion 42b depending on the amount of introduced encapsulating resin into the through-hole 42. The residual air A moves into the through-hole 42. A movement of the residual air A may occur due to the inflow of the encapsulating resin into the through-hole 42. The residual air A moved into the through-hole 42 forms the cavity portion 70 at the second end 52 of the resin-filled portion 50 within the through-hole 42.

In the releasing process ST44, the semiconductor device 1 in which the encapsulating resin layer 30 is formed is released from the mold portion 210. Then, the semiconductor device 1A is completed through the releasing process ST44, as illustrated in FIG. 16D.

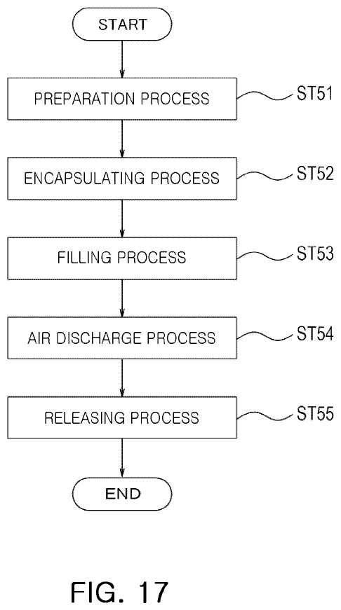

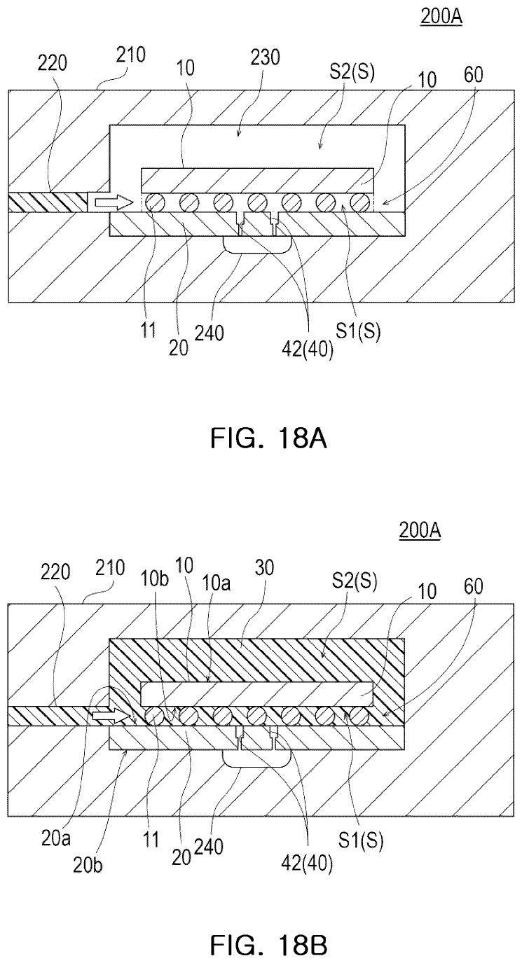

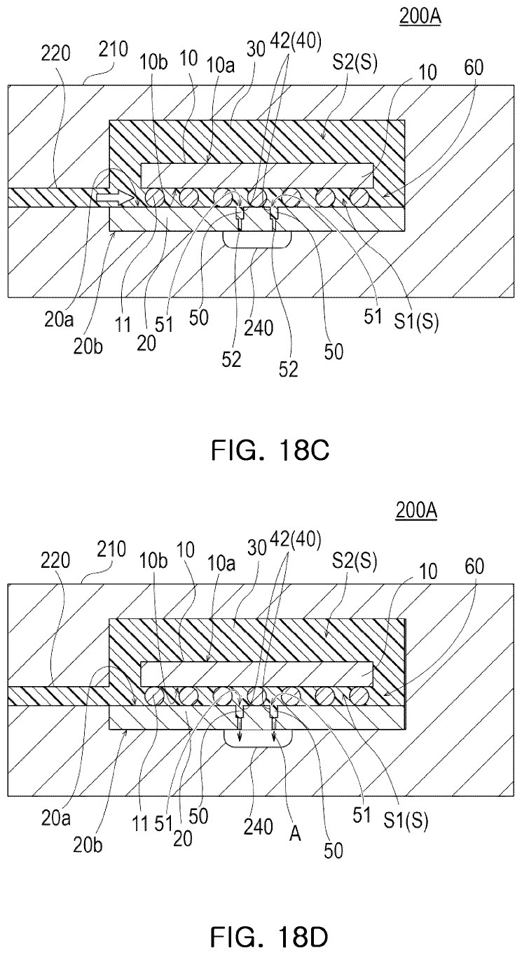

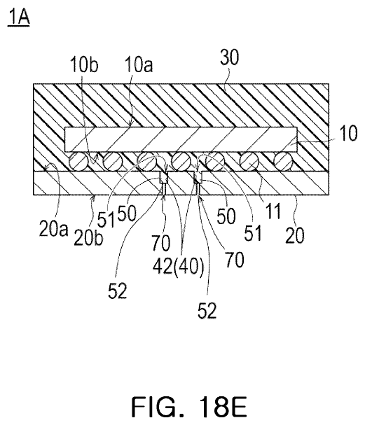

Next, a sixth example manufacturing method, an example semiconductor device manufacturing method (hereinafter referred to as “manufacturing method F”), will be described. FIG. 17 is a flow chart illustrating a series of processes of the manufacturing method F. FIGS. 18A to 18E are configuration diagrams illustrating the processes of the manufacturing method F.

The manufacturing method F differs from manufacturing method A in that the carrier substrate 100 is not disposed on the circuit board 20 and the residual air A is discharged to the exhaust space 240 formed in the mold portion 210 of the mold device 200. The manufacturing method F uses the mold device 200A, as illustrated in FIG. 18A. The exhaust space 240 communicates with the second hole portion 42b of the through-hole 42, and is filled with residual air A discharged through the through-hole 42.

As illustrated in FIG. 17, the manufacturing method F includes a preparation process ST51, an encapsulating process ST52, a filling process ST53, an air discharge process ST54, and a releasing process ST55. Hereinafter, the manufacturing method F is described as a method for manufacturing a semiconductor device 1A.

In the preparation process ST51, a module component 60 included in the semiconductor device 1A and a mold device 200A used to form an encapsulating resin layer 30 are prepared, respectively.

As illustrated in FIG. 18A and FIG. 18B, in the encapsulating process ST52, in a state in which the module component 60 is disposed in the cavity 230 formed by the mold portion 210 of the mold device 200B, the encapsulating resin is filled in the cavity 230 to form an encapsulating resin layer 30 in the encapsulating space S.

As illustrated in FIG. 18C, in the filling process ST53, a portion of the encapsulating resin injected into the cavity 230 in the encapsulating process ST52 is filled into the through-hole 42. The encapsulating resin is filled into at least the first hole portion 42a, and may also be partially introduced into the second hole portion 42b depending on the amount of the encapsulating resin introduced into the through-hole 42. The encapsulating resin filled into the through-hole 42 forms a resin-filled portion 50. A cavity portion 70 is formed between the second end 52 of the resin-filled portion 50 and the second surface 20b of the circuit board 20.

As illustrated in FIG. 18D, in the air exhaust process ST54, the residual air A passing through the through-hole 42 is discharged into the exhaust space 240. A movement of residual air A may occur by the inflow of the encapsulating resin into the through-hole 42. Accordingly, the exhaust space 240 is filled with residual air A.

In the releasing process ST55, the semiconductor device 1 in which the encapsulating resin layer 30 is formed is released from the mold portion 210. Then, the semiconductor device 1A is completed through the releasing process ST55, as illustrated in FIG. 18E.

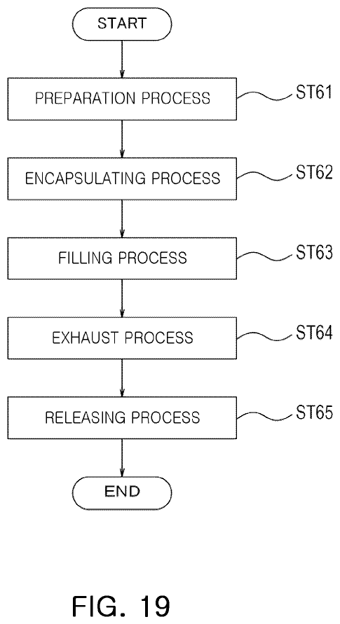

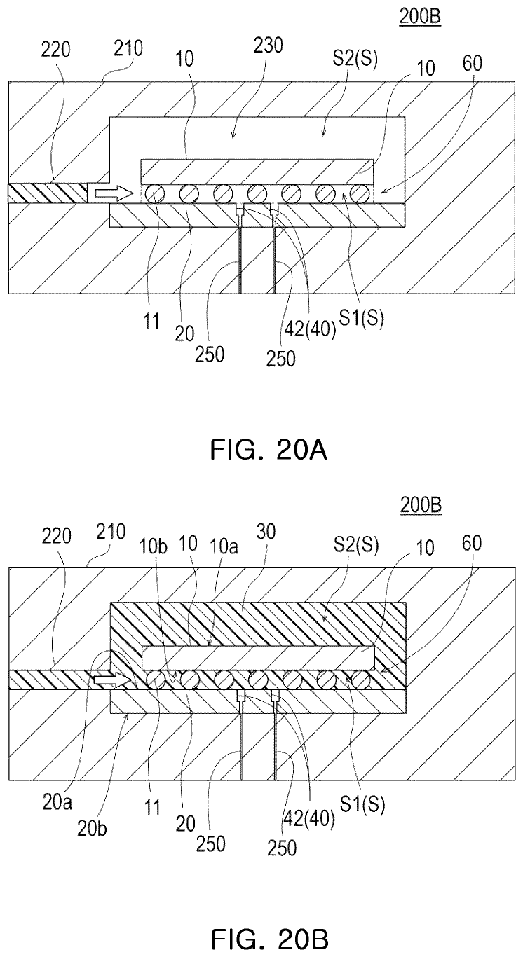

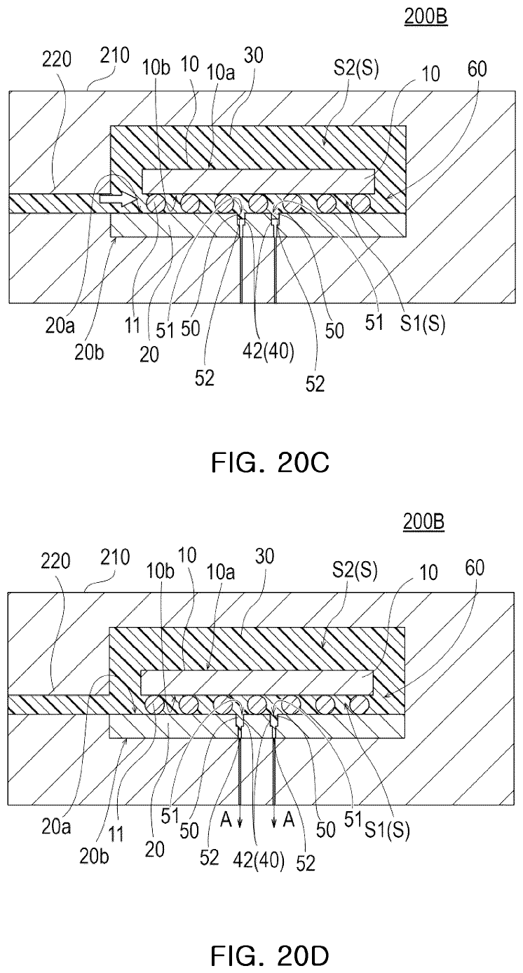

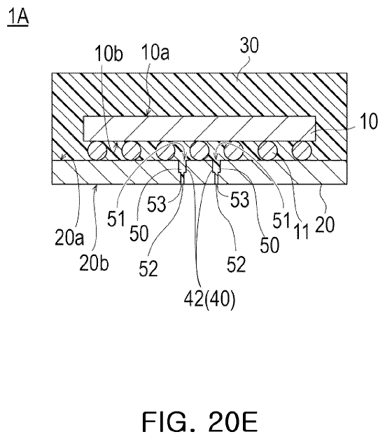

Next, a seventh example manufacturing method, an example semiconductor device manufacturing method (hereinafter referred to as “manufacturing method G”), will be described. FIG. 19 is a flow chart illustrating a series of processes of the manufacturing method G. FIGS. 20A to 20E are configuration diagrams illustrating the processes of the manufacturing method G.

The manufacturing method G differs from the manufacturing method A in that the carrier substrate 100 is not disposed on the circuit board 20, and the residual air A is discharged through the exhaust path 250 penetrating from the cavity 230 externally of the mold device 200B. The manufacturing method G uses the mold device 200B as illustrated in FIG. 20A.

The manufacturing method G includes a preparation process ST61, an encapsulating process ST62, a filling process ST63, an exhaust process ST64, and a releasing process ST65, as illustrated in FIG. 19. Hereinafter, the manufacturing method G is described as a method for manufacturing a semiconductor device 1A.

In the preparation process ST61, the module component 60 included in the semiconductor device 1A and the mold device 200B used to form the encapsulating resin layer 30 are prepared, respectively.

In the encapsulating process ST62, as illustrated in FIGS. 20A and 20B, in a state in which the module component 60 is disposed in the cavity 230 formed by the mold portion 210 of the mold device 200B, the encapsulating resin is filled into the cavity 230 to form an encapsulating resin layer 30 in the encapsulating space S.

As illustrated in FIG. 20C, in the filling process ST63, a portion of the encapsulating resin injected into the cavity 230 in the encapsulating process ST52 is filled into the through-hole 42. The encapsulating resin is filled into at least the first hole portion 42a, and is also partially introduced into the second hole portion 42b by the amount of the encapsulating resin introduced into the through-hole 42. The encapsulating resin filled into the through-hole 42 forms a filled resin portion 50.

As illustrated in FIG. 20D, in the exhaust process ST64, the residual air A passing through the through-hole 42 is exhausted externally of the mold device 200B through the exhaust path 250. A movement of the residual air A may occur due to the inflow of the encapsulating resin into the through-hole 42.

In the releasing process ST65, the semiconductor device 1A in which the encapsulating resin layer 30 is formed is released from the mold portion 210. The second end 52 of the resin-filled portion 50 formed in the through-hole 42 may be attached to a bottom of the mold portion 210 before the releasing process. For this reason, the semiconductor device 1 is released in a state in which a portion of the resin-filled portion 50 is attached to the mold portion 210 near an opening of the through-hole 42. Accordingly, as illustrated in FIG. 3B, the semiconductor device 1A may be formed by shearing a portion of the resin-filled portion 50 and a sheared portion 53 may be formed in the second end 52 of the resin-filled portion 50. Then, as illustrated in FIG. 20E, the semiconductor device 1A is completed through the releasing process ST65.

Meanwhile, in the manufacturing method G, in the filling process ST63, the encapsulating resin is introduced into the through-hole 42 to form a resin-filled portion 50. However, the encapsulating resin may be accumulated inside the through-hole 42 due to the amount of the introduced encapsulating resin and may not be attached to the mold portion 210. In this case, as illustrated in FIG. 4, a cavity portion 70 is formed at the second end 52 of the resin-filled portion 50 in the through-hole 42. Additionally, the cavity portion 70 may be formed in the second hole portion 42b even when a hole diameter of the second hole portion 42b is a length through which only the residual air A is able to flow. In this case, the resin-filled portion 50 is formed only in the first hole portion 42a.

However, the manufacturing methods A to G described above may include a through-hole forming process of forming one or more through-holes 41 or through-holes 42 penetrating through the circuit board 20 and communicating with the first encapsulating space S1, in the position overlapping the projection surface in the thickness direction of the semiconductor chip 10.

The through-hole forming process may be formed by drilling processing from a side of the second surface 20b of the circuit board 20. Cutting chips during the drilling process may be discharged from a side opposite to a cutting direction. For this reason, the semiconductor device 1 may prevent the cutting chips from remaining on the first surface 20a of the circuit board 20. The through-hole forming process may be performed, for example, before the encapsulating process of each manufacturing method. Additionally, in the through-hole forming process, when forming the through-hole 41 or the through-hole 42, the carrier substrate through-hole 110 may be formed simultaneously in the carrier substrate 100 used in the manufacturing method A or the manufacturing method B.

Furthermore, the manufacturing methods A to G described above discharge the residual air A to the discharge portion 40 (e.g., the through-hole 41 or the through-hole 42) by the flow of the encapsulating resin filled in the encapsulating space S. However, the manufacturing methods A to G may also forcibly suction and discharge the residual air A from the first encapsulating space S1 by connecting a suction mechanism, to the discharge portion 40. When the timing of a suction start by the suction mechanism is, for example, after the inflow of the encapsulating resin into the first encapsulating space S1, the residual air A may be efficiently discharged without suctioning unnecessary air.

As described above, the semiconductor device 1 according to some example implementations includes the circuit board 20, the semiconductor chip 10 mounted on the circuit board 20, and the encapsulating resin layer 30 encapsulating the semiconductor chip 10 with the encapsulating resin. The encapsulating resin layer 30 is formed in the encapsulating space S including a first encapsulating space S1 formed between the circuit board 20 and the semiconductor chip 10 and the second encapsulating space S2 formed to cover the semiconductor chip 10. The circuit board 20 has the discharge portion 40 discharging the residual air A in the first encapsulating space S1 externally, in the position overlapping the projection surface in the thickness direction of the semiconductor chip 10. The resin-filled portion 50 formed of the encapsulating resin is formed inside the through-hole 41, and the circuit board 20 does not have the solid resin portion 80 formed of the encapsulating resin on the second surface 20b.

By such a configuration, in the semiconductor device 1, the residual air A in the first encapsulating space S1 is discharged through the discharge portion 40, so that when forming the encapsulating resin layer 30, the occurrence of voids between the semiconductor chip 10 and the circuit board 20 may be suppressed. Additionally, in the semiconductor device 1, since the resin-filled portion 50 is formed within the discharge portion 40, the bonding strength between the circuit board 20 and the encapsulating resin layer 30 is improved. Furthermore, in the semiconductor device 1, since the solid resin portion 80 by the encapsulating resin is not formed on the second surface 20b of the circuit board 20, the case of mounting is improved, and thus, the semiconductor device 1 may be mounted on a micro-shaped electronic device product without limitation.

The method for manufacturing a semiconductor device according to some example implementations is a method for forming the encapsulating resin layer 30 for encapsulating the semiconductor chip 10 using the mold device 200, on the module component 60 having a circuit board 20 and a semiconductor chip 10 mounted on the circuit board 20, and the encapsulating resin layer 30 is formed in the encapsulating space S including the first encapsulating space S1 formed between the circuit board 20 and the semiconductor chip 10 and the second encapsulating space S2 formed to cover the semiconductor chip 10. In the circuit board 20, one or more through-holes 41 are formed from the first surface 20a facing the semiconductor chip 10 to the second surface 20b opposite to the first surface 20a so that the first encapsulating space S1 communicates with the outside of the circuit board 20, in the position overlapping the projection surface in the thickness direction of the semiconductor chip 10. Additionally, the method for manufacturing a semiconductor device includes a disposition process of disposing the carrier substrate 100 on the second surface 20b of the circuit board 20 of the module component 60, an encapsulating process of encapsulating the encapsulating space S by injecting the encapsulating resin into the cavity 230, in a state in which the module portion 60 is disposed in the cavity 230 formed in the mold portion 210 of the mold device 200, a filling process of filling a portion of the encapsulating resin introduced into the first encapsulating space S1 into the through-hole 41, a releasing process of releasing a semiconductor device 1 formed of the module component 60 encapsulated with the encapsulating resin from the mold portion 210, and a peeling process of peeling the carrier substrate 100 from the released semiconductor device 1.

Another method for manufacturing a semiconductor device according to some example implementations is a method for forming the encapsulating resin layer 30 encapsulating the semiconductor chip 10 using the mold device 200, in the module component 60 having the circuit board 20 and the semiconductor chip 10 mounted on the circuit board 20. The encapsulating resin layer 30 is formed in the encapsulating space S including the first encapsulating space S1 formed between the circuit board 20 and the semiconductor chip 10 and the second encapsulating space S2 formed to cover the semiconductor chip 10. In the circuit board 20, one or more through-holes 41 are formed from the first surface 20a facing the semiconductor chip 10 to the second surface 20b opposite to the first surface 20a so that the first encapsulating space S1 communicates with the outside of the circuit board 20, in the position overlapping the projection surface in the thickness direction of the semiconductor chip 10. Additionally, the method includes the encapsulating process of injecting the encapsulating resin into the cavity 230 and encapsulating the encapsulating space S with the encapsulating resin, in a state in which the module component 60 is disposed in the cavity 230 formed in the mold portion 210 of the mold device 200, and the filling process of filling a portion of the encapsulating resin introduced into the first encapsulating space S1 into the through-holes 41.

By such a configuration, in the semiconductor device 1 manufactured by the manufacturing method described above, since the residual air A in the first encapsulating space S1 may be discharged through the through-hole 41, when forming the encapsulating resin layer 30, the occurrence of voids between the semiconductor chip 10 and the circuit board 20 may be suppressed. Additionally, in the semiconductor device 1, since the resin-filled portion 50 is formed in the through-hole 41, the adhesive strength between the circuit board 20 and the encapsulating resin layer 30 is improved. Furthermore, in the semiconductor device 1, since the solid resin portion 80 by the encapsulating resin is not formed on the second surface 20b of the circuit board 20, the ease of mounting is improved, and the semiconductor device 1 may be mounted on a micro-shaped electronic device product without limitation.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method for manufacturing a semiconductor device, comprising:
forming an encapsulating resin layer on a module component using a mold device, the module component including a circuit board and a semiconductor chip on the circuit board, the encapsulating resin layer encapsulating the semiconductor chip,
wherein the encapsulating resin layer is formed in an encapsulating space including a first encapsulating space between the circuit board and the semiconductor chip and a second encapsulating space covering the semiconductor chip,
wherein one or more through-holes are defined in the circuit board and extend from a first surface of the circuit board facing the semiconductor chip to a second surface of the circuit board that is opposite to the first surface, the first encapsulating space being in fluid communication with an outside of the circuit board, and
wherein the one or more through-holes are positioned to overlap the semiconductor chip in a thickness direction of the semiconductor chip, and
wherein forming the encapsulating resin layer comprises:
disposing a carrier substrate on the second surface of the circuit board;
injecting an encapsulating resin into a cavity to encapsulate the encapsulating space, the cavity being defined at a mold portion of the mold device and receiving the module component;
filling the one or more through-holes with a portion of the encapsulating resin introduced into the first encapsulating space;
releasing, from the mold portion of the mold device, the semiconductor device including the module component encapsulated with the encapsulating resin, and
removing the carrier substrate from the released semiconductor device.

2. The method of claim 1,
wherein the mold device has an exhaust space defined at the mold portion and being in fluid communication with the one or more through-holes, and
wherein the method further comprises:
injecting the encapsulating resin while residual air is discharged from the first encapsulating space through the one or more through-holes into the exhaust space,
wherein removing the carrier substrate from the released semiconductor device comprises:
removing a solid resin portion formed by the encapsulating resin injected into the exhaust space.

3. The method of claim 1, comprising:
forming the one or more through-holes extending through the circuit board in the thickness direction and in fluid communication with the first encapsulating space.

4. The method of claim 1,
wherein the one or more through-holes are positioned near a center of the semiconductor chip and in the thickness direction.

5. The method of claim 1,
wherein the one or more through-holes are positioned near a center of the semiconductor chip by drilling processing from the second surface of the circuit board in the thickness direction.

6. The method of claim 1,
wherein the encapsulating resin is a thermosetting resin having a viscosity of more than 0.01 Pa·s in an uncured state.

7. A method for manufacturing a semiconductor device, comprising:
forming an encapsulating resin layer on a semiconductor device using a mold device, the semiconductor device including a circuit board and a semiconductor chip, the encapsulating resin layer encapsulating the semiconductor chip,
wherein the encapsulating resin layer is formed in an encapsulating space including a first encapsulating space between the circuit board and the semiconductor chip and a second encapsulating space covering the semiconductor chip,
wherein, in the circuit board, one or more through-holes are positioned to overlap the semiconductor chip in a thickness direction of the semiconductor chip, at least one of the one or more through-holes extending from a first surface of the circuit board facing the semiconductor chip to a second surface of the circuit board that is opposite to the first surface, the first encapsulating space being in fluid communication with an outside of the circuit board, and
wherein forming the encapsulating resin layer comprises:
filling a cavity with an encapsulating resin, the cavity being defined at a mold portion of the mold device and receiving the semiconductor device; and
filling the one or more through-holes with the encapsulating resin introduced into the first encapsulating space.

8. The method of claim 7, wherein the mold device has an exhaust path extending from the cavity to an outside of the mold device, the exhaust path being in fluid communication with the one or more through-holes, and
wherein the method further includes exhausting residual air in the first encapsulating space from the exhaust path through the one or more through-holes.

9. The method of claim 8, wherein the exhaust path is defined by electrical discharge machining, the exhaust path being positioned near a center of the semiconductor chip.

10. The method of claim 8, wherein the mold portion has a fitting groove defined in a region including a formation position of the exhaust path and a fitting member fitted into the fitting groove, and
wherein the exhaust path includes a gap defined by the fitting member being fitted into the fitting groove, the exhaust path being positioned near a center of the semiconductor chip.

11. The method of claim 7, comprising:
forming the one or more through-holes extending through the circuit board in the thickness direction and in fluid communication with the first encapsulating space.

12. The method of claim 7,
wherein the one or more through-holes are positioned near a center of the semiconductor chip and in the thickness direction.

13. The method of claim 7,
wherein the one or more through-holes are positioned near a center of the semiconductor chip by drilling processing from the second surface of the circuit board in the thickness direction.

14. The method of claim 7,
wherein the encapsulating resin is a thermosetting resin having a viscosity of more than 0.01 Pa·s in an uncured state.
